(19) United States
(12) Patent Application Publication
(10) Pub. No.: US 2024/0094353 A1
(43) Pub. Date: Mar. 21, 2024

(54) LIDAR SYSTEM, APPARATUS COMMUNICATING WITH THE LIDAR SYSTEM, AND APPARATUS LOCATED IN A FIELD OF VIEW (FOV) OF THE LIDAR SYSTEM

(71) Applicant: LeddarTech Inc., Quebec (CA)

(72) Inventors: Ricardo Ferreira, Ottobrunn (DE); Stefan Hadrath, Falkensee (DE); Peter Hoehmann, Berlin (DE); Herbert Kaestle, Traunstein (DE); Florian Kolb, Jena (DE); Norbert Magg, Berlin (DE); Jiye Park, Munich (DE); Tobias Schmidt, Garching (DE); Martin Schnarrenberger, Berlin (DE); Norbert Haas, Langenau (DE); Helmut Horn, Achberg (DE); Bernhard Siessegger, Unterschleissheim (DE); Guido Angenendt, Munich (DE); Charles Braquet, Munich (DE); Gerhard Maierbacher, Munich (DE); Oliver Neitzke, Berlin (DE); Sergey Khrushchev, Regensburg (DE)

(21) Appl. No.: 18/514,827

(22) Filed: Nov. 20, 2023

Related U.S. Application Data
(63) Continuation of application No. 18/318,538, filed on Jan. 1, 0001.
Application No. 18/318,538 is a continuation of application No. 16/809,587, filed on Mar. 5, 2020, now Pat. No. 11,726,184.

(30) Foreign Application Priority Data
Mar. 8, 2019 (DE) 102019203175.7
Apr. 16, 2019 (DE) 102019205514.1
May 14, 2019 (DE) 102019206939.8
Jun. 12, 2019 (DE) 102019208489.3
Jul. 17, 2019 (DE) 102019210528.9
Sep. 2, 2019 (DE) 102019213210.3
Sep. 23, 2019 (DE) 102019214455.1
Oct. 24, 2019 (DE) 102019216362.9
Nov. 6, 2019 (DE) 102019217097.8
Nov. 22, 2019 (DE) 102019218025.6
Dec. 17, 2019 (DE) 102019219775.2
Jan. 24, 2020 (DE) 102020200833.7
Feb. 10, 2020 (DE) 102020201577.5
Feb. 17, 2020 (DE) 102020201900.2
Feb. 25, 2020 (DE) 102020202374.3

(51) Int. Cl. G01S 7/481; G01S 7/484; G01S 17/931

(52) U.S. Cl. CPC G01S 7/4817; G01S 7/4811; G01S 7/4815; G01S 7/4816; G01S 7/484; G01S 17/931

(57) ABSTRACT

The present disclosure provides a light detection and ranging (LIDAR) system, which comprises: a distance measuring unit configured to emit a plurality of first pulses towards an object located in a field of view (FOV), wherein the object is associated with one or more markers; and a detector configured to receive at least one second pulse from the one or more markers of the object, wherein each of the at least one second pulse indicates object information identifying the object.

### CROSS-REFERENCE TO RELATED APPLICATIONS

The present application is a continuation of U.S. patent application Ser. No. 18/318,538, filed May 16, 2023, which is a continuation of U.S. patent application Ser. No. 16/809,587, filed on Mar. 5, 2020, now U.S. patent number 11; 726,184, which claims priority from and the benefit of: (i) German Application No.: 10 2019 205 514.1, filed on Apr. 16, 2019, (ii) German Application No.: 10 2019 214 455.1, filed on Sep. 23, 2019, (iii) German Application No.: 10 2019 216 362.9, filed on Oct. 24, 2019, (iv) German Application No.: 10 2020 201 577.5, filed on Feb. 10, 2020, (v) German Application No.: 10 2019 217 097.8, filed on Nov. 6, 2019, (vi) German Application No.: 10 2020 202 374.3, filed on Feb. 25, 2020, (vii) German Application No.: 10 2020 201 900.2, filed on Feb. 17, 2020. (viii) German Application No,: 10 2019 203 175.7, filed on Mar. 8, 2019, (ix) German Application No.: 10 2019 218 025.6, filed on Nov. 22, 2019, (x) German Application No.: 10 2019 219 775.2, filed on Dec. 17, 2019, (xi) German Application No.: 10 2020 200 833.7, filed on Jan. 24, 2020, (xii) German Application No.: 10 2019 208 489.3, filed on Jun. 12, 2019, (xiii) German Application No.: 10 2019 210 528.9, filed on Jul. 17, 2019. (xiv) German Application No.: 10 2019 206 939.8, filed on is May 14, 2019, and (xv) German Application No.: 10 2019 213 210.3, filed on Sep. 2, 2019. The contents of each of the aforementioned U.S. and German applications are incorporated herein by reference in theft entirety.

### TECHNICAL HELD

The technical field of the present disclosure relates generally to light detection and ranging (LIDAR) systems and methods that use light detection and ranging technology. This disclosure is focusing on A light detection and ranging (LIDAR) system, an apparatus communicating with the LIDAR system, and an apparatus located in a field of view (FOV) of the LIDAR system.

### BACKGROUND

There are numerous studies and market forecasts, which predict that future mobility and transportation will shift from vehicles supervised by a human operator to vehicles with an increasing level of autonomy towards fully autonomous, self-driving vehicles. This shift; however, will not be an abrupt change but rather a gradual transition with different levels of autonomy, defined for example by SAE International (Society of Automotive Engineers) in SAE J3016 in-between. Furthermore, this transition will not take place in a simple linear manner, advancing from one level to the next level, while rendering all previous levels dispensable, Instead; it is expected that these levels of different extent of autonomy will co-exist over longer periods of time and that many vehicles and their respective sensor systems will be able to support more than one of these levels.

Depending on various factors, a human operator may actively switch for example between different SAE levels, depending on the vehicle's capabilities, or the vehicles operation system may request or initiate such a switch, typically with a timely information and acceptance period to possible human operators of the vehicles. These factors may include internal factors such as individual preference; level of driving experience or the biological state of a human driver and external factors such as a change of environmental conditions like weather, traffic density or unexpected traffic complexities.

It is important to note that the above-described scenario for a future is not a theoretical, far-away eventuality. In fact, already today, a large variety of so-called Advanced Driver Assistance Systems (ADAS) has been implemented in modern vehicles, which clearly exhibit characteristics of autonomous vehicle control. Current ADAS systems may be configured for example to alert a human operator in dangerous situations (e.g. lane departure warning) but in specific driving situations, some ADAS systems are able to takeover control and perform vehicle steering operations without active selection or intervention by a human operator, Examples may include convenience-driven situations such as adaptive cruise control but also hazardous situations like in the case of lane keep assistants and emergency break assistants.

The above-described scenarios all require vehicles and transportation systems with a tremendously increased capacity to perceive; interpret and react on their surroundings. Therefore, it is not surprising that remote environmental sensing systems will be at the heart of future mobility.

Since modern traffic can be extremely complex due to a large number of heterogeneous traffic participants, changing environments or insufficiently mapped or even unmapped environments, and due to rapid, interrelated dynamics, such sensing systems will have to be able to cover a broad range of different tasks, which have to be performed with a high level of accuracy and reliability. It turns out that there is not a single “one fits all” sensing system that can meet all the required features relevant for semi-autonomous or fully autonomous vehicles. Instead, future mobility requires different sensing technologies and concepts with different advantages and disadvantages. Differences between sensing systems may be related to perception range, vertical and horizontal field of view (FOV), spatial and temporal resolution, speed of data acquisition, etc. Therefore, sensor fusion and data interpretation, possibly assisted by Deep Neuronal Learning (DNL) methods and other Neural Processor Units (NFU) methods for more complex tasks, like judgment of a traffic situation and generation of derived vehicle control functions, may be necessary to cope with such complexities. Furthermore, driving and steering of autonomous vehicles may require a set of ethical rules and commonly accepted traffic regulations.

Among these sensing systems, LIDAR sensing systems are expected to play a vital role, as well as camera-based systems, possibly supported by radar and ultrasonic systems. With respect to a specific perception task, these systems may operate more or less independently of each other. However, in order to increase the level of perception (e.g. in terms of accuracy and range), signals and data acquired by different sensing systems may be brought together in so-called sensor fusion systems. Merging of sensor data is not only necessary to refine and consolidate the measured results but also to increase the confidence in sensor results by resolving possible inconsistencies and contradictories and by providing a certain level of redundancy. Unintended spurious signals and intentional adversarial attacks may play a role in this context as well.

For an accurate and reliable perception of a vehicle's surrounding, not only vehicle-internal sensing systems and measurement data may be considered but also data and information from vehicle-external sources. Such vehicle-external sources may include sensing systems connected to other traffic participants, such as preceding and oncoming vehicles, pedestrians and cyclists, but also sensing systems mounted on road infrastructure elements like traffic lights, traffic signals, bridges, elements of road construction sites and central traffic surveillance structures. Furthermore, data and information may come from far-away sources such as traffic teleoperators and satellites of global positioning systems (e.g. GPS).

Therefore, apart from sensing and perception capabilities, future mobility will also heavily rely on capabilities to communicate with a wide range of communication partners. Communication may be unilateral or bilateral and may include various wireless transmission technologies, such as WLAN, Bluetooth and communication based on radio frequencies and visual or non-visual light signals. It is to be noted that some sensing systems, for ex-ample LIDAR sensing systems, may be utilized for both sensing and communication tasks, which makes them particularly interesting for future mobility concepts. Data safety and security and unambiguous identification of communication partners are examples where light-based technologies have intrinsic advantages over other wireless communication technologies. Communication may need to be encrypted and tamper-proof.

From the above description, it becomes clear also that future mobility has to be able to handle vast amounts of data, as several tens of gigabytes may be generated per driving hour. This means that autonomous driving systems have to acquire, collect and store data at very high speed, usually complying with real-time conditions. Furthermore, future vehicles have to be able to interpret these data, i.e. to derive some kind of contextual meaning within a short period of time in order to plan and execute required driving maneuvers. This demands complex software solutions, making use of is advanced algorithms. It is expected that autonomous driving systems will including more and more elements of artificial intelligence, machine and self-learning, as well as Deep Neural Networks (DNN) for certain tasks, e.g. visual image recognition, and other Neural Processor Units (NFU) methods for more complex tasks, like judgment of a traffic situation and generation of derived vehicle control functions, and the like. Data calculation, handling, storing and retrieving may require a large amount of processing power and hence electrical power.

In an attempt to summarize and conclude the above paragraphs, future mobility will involve sensing systems, communication units, data storage devices, data computing and signal processing electronics as well as advanced algorithms and software solutions that may include and offer various ethical settings. The combination of all these elements is constituting a cyber-physical world, usually denoted as the Internet of things (IoT). In that respect, future vehicles represent some kind of IoT device as well and may be called “Mobile IoT devices”.

Such “Mobile IoT devices” may be suited to transport people and cargo and to gain or provide information. It may be noted that future vehicles are sometimes also called “smartphones on wheels”, a term which surely reflects some of the capabilities of future vehicles. However, the term implies a certain focus towards consumer-related new features and gimmicks. Although these aspects may certainly play a role, it does not necessarily reflect the huge range of future business models, in particular data-driven business models, that can be envisioned only at the present moment of time but which are likely to center not only on personal, convenience driven features but include also commercial, industrial or legal aspects.

New data-driven business models will focus on smart, location-based services, utilizing for example self-learning and prediction aspects, as well as gesture and language processing with Artificial Intelligence as one of the key drivers. All this is fueled by data, which will be generated in vast amounts in automotive industry by a large fleet of future vehicles acting as mobile digital platforms and by connectivity networks linking together mobile and stationary IoT devices.

New mobility services including station-based and free-floating car sharing, as well as ride-sharing propositions have already started to disrupt traditional business fields. This trend will continue, finally providing roto-taxi services and sophisticated Transportation-as-a-Service (TaaS) and Mobility-as-a-Service (MaaS) solutions.

Electrification, another game-changing trend with respect to future mobility, has to be considered as well. Hence, future sensing systems will have to pay close attention to system efficiency, weight and energy-consumption aspects. In addition to an overall minimization of energy consumption, also context-specific optimization strategies, depending for example on situation-specific or location-specific factors, may play an important role.

Energy consumption may impose a limiting factor for autonomously driving electrical vehicles. There are quite a number of energy consuming devices like sensors, for example RADAR, LIDAR, camera, ultrasound, Global Navigation Satellite System (GNSS/GPS), sensor fusion equipment, processing power, mobile entertainment equipment, heater, fans, Heating, Ventilation and Air Conditioning (HVAC), Car-to-Car (C2C) and Car-to-Environment (C2X) communication, data encryption and decryption, and many more, all leading up to a high power consumption. Especially data processing units are very power hungry. Therefore, it is necessary to optimize all equipment and use such devices in intelligent ways so that a higher battery mileage can be sustained.

Besides new services and data-driven business opportunities, future mobility is expected also to provide a significant reduction in traffic-related accidents. Based on data from the Federal Statistical Office of is Germany (Destatis, 2018), over 98% of traffic accidents are caused, at least in part by humans. Statistics from other countries display similarly clear correlations.

Nevertheless, it has to be kept in mind that automated vehicles will also introduce new types of risks, which have not existed before. This applies to so far unseen traffic scenarios, involving only a single automated driving system as well as for complex scenarios resulting from dynamic interactions between a plurality of automated driving system. As a consequence, realistic scenarios aim at an overall positive risk balance for automated driving as compared to human driving performance with a reduced number of accidents, while tolerating to a certain extent some slightly negative impacts in cases of rare and unforeseeable driving situations. This may be regulated by ethical standards that are possibly implemented in soft- and hardware.

Any risk assessment for automated driving has to deal with both, safety and security related aspects: safety in this context is focusing on passive adversaries for example due to malfunctioning systems or system components, while security is focusing on active adversaries for example due to intentional attacks by third parties.

In the following a non-exhaustive enumeration is given for safety-related and security-related factors, with reference to “Safety first for Automated Driving”, a white paper published in 2010 by authors from various Automotive OEM, Tier-1 and Tier-2 suppliers.

Safety assessment: to meet the targeted safety goals, methods of verification and validation have to be implemented and executed for all relevant systems and components. Safety assessment may include safety by design principles, quality audits of the development and production processes, the use of redundant sensing and analysis components and many other concepts and methods.

Safe operation: any sensor system or otherwise safety-related system might be prone to degradation, i.e. system performance may decrease over time or a system may even fail completely (e.g. being unavailable). To ensure safe operation, the system has to be able to compensate for such performance losses for example via redundant sensor systems. In any case, the system has to be configured to transfer the vehicle into a safe condition with acceptable risk. One possibility may include a safe transition of the vehicle control to a human vehicle operator.

Operational design domain: every safety-relevant system has an operational domain (e.g. with respect to environmental conditions such as temperature or weather conditions including rain, snow and fog) inside which a proper operation of the system has been specified and validated. As soon as the system gets outside of this domain, the system has to be able to compensate for such a situation or has to execute a safe transition of the vehicle control to a human vehicle operator.

Safe layer: the automated driving system needs to recognize system limits in order to ensure that it operates only within these specified and verified limits. This includes also recognizing limitations with respect to a safe transition of control to the vehicle operator.

User responsibility: it must be clear at all times which driving tasks remain under the user's responsibility. In addition, the system has to be able to determine factors, which represent the biological state of the user (e.g. state of alertness) and keep the user informed about their responsibility with respect to the user's remaining driving tasks.

Human Operator-initiated handover: there have to be clear rules and explicit instructions in case that a human operator requests an engaging or disengaging of the automated driving system.

Vehicle initiated handover: requests for such handover operations have to be clear and manageable by the human operator, including a sufficiently long time period for the operator to adapt to the current traffic situation. In case it turns out that the human operator is not available or not capable of a safe takeover, the automated driving system must be able to perform a minimal-risk maneuver.

Behavior in traffic: automated driving systems have to act and react in an easy-to-understand way so that their behavior is predictable for other road users. This may include that automated driving systems have to observe and follow traffic rules and that automated driving systems inform other road users about theft intended behavior, for example via dedicated indicator signals (optical, acoustic).

Security: the automated driving system has to be protected against security threats (e.g. cyber-attacks), including for example unauthorized access to the system by third party attackers. Furthermore, the system has to be able to secure data integrity and to detect data corruption, as well as data forging. Identification of trustworthy data sources and communication partners is another important aspect. Therefore, security aspects are, in general, strongly linked to cryptographic concepts and methods.

Data recording: relevant data related to the status of the automated driving system have to be recorded, at least in well-defined cases. In addition, traceability of data has to be ensured, making strategies for data management a necessity, including concepts of bookkeeping and tagging. Tagging may comprise, for example, to correlate data with location information, e.g. GPS-information.

In the following disclosure, various aspects are disclosed which may be related to the technologies, concepts and scenarios presented in the section “BACKGROUND”. This disclosure is focusing on LIDAR Sensor Systems, Controlled LIDAR Sensor Systems and LIDAR Sensor Devices as well as Methods for LIDAR Sensor Management. As illustrated in the above remarks, automated driving systems are extremely complex systems including a huge variety of interrelated sensing systems, communication units, data storage devices, data computing and signal processing electronics as well as advanced algorithms and software solutions.

### SUMMARY

A first aspect of the present disclosure provides a light detection and ranging (LIDAR) system. The LIDAR system comprises: a distance measuring unit configured to emit a plurality of first pulses towards an object located in a field of view (FOV), wherein the object is associated with one or more markers; and a detector configured to receive at least one second pulse from the one or more markers of the object, wherein each of the at least one second pulse indicates object information identifying the object.

In accordance with the preceding aspect, each of the at least one second pulse is configured with a particular wavelength which represents an object class of the object.

In accordance with the preceding aspect, the object information is modulated on the at least one second pulse.

In accordance with the preceding aspect, the object information is modulated on the at least one second pulse via an amplitude modulation.

In accordance with the preceding aspect, an intensity distribution of the plurality of first pulses has at least one subset that overlaps with an intensity distribution of the at least one second pulse.

In accordance with the preceding aspect, the object information is wavelength-coded on the at least one second pulse.

In accordance with the preceding aspect, the system further comprising at least one filter configured to receive the at least one second pulse from the one or more markers and pass though some of the at least one second pulse at a given wavelength.

In accordance with the preceding aspect, wherein the one or more markers are disposed on a garment.

In accordance with the preceding aspect, wherein the one or more marker includes a passive marker.

In accordance with the preceding aspect, wherein the one or more marker includes an active marker.

In accordance with the preceding aspect, the object information includes at least one of position information, movement trajectories and object class.

In accordance with the preceding aspect, each of the at least one second pulse includes amplified echo pulse.

A second aspect of the present disclosure provides an apparatus configured to communicate with a light detection and ranging (LIDAR) system that is associated with a first object in a traffic environment. The apparatus comprising: an acquisition and information unit configured to detect a signal pulse emitted by the LIDAR system; a control device configured to determine if the detected signal pulse satisfies at least one threshold setting; and a signal generating device configured to, in response to the detected signal pulse satisfying the at least one threshold setting, output an information signal noticeable by human senses.

In accordance with the preceding aspect, the information signal includes at least one of an optical signal, an acoustic signal, and a mechanical vibration.

In accordance with the preceding aspect, wherein the signal pulse comprises at least one of an object type, an object classification, an object velocity, an object trajectory, a position, a distance, an acceleration, and a method of movement of the first object.

In accordance with the preceding aspect, wherein the at least one of an object type, an object classification, an object velocity, an object trajectory, a position, a distance, an acceleration, and a method of movement of the first object is included in the signal pulse by frequency modulation, pulse modulation or a pulse code.

In accordance with the preceding aspect, wherein the information signal includes an optical signal and wherein the signal generating device comprises one or more light sources and one or more optical waveguides, wherein each of the one or more optical waveguides is configured to be coupled to a respective one of the one or more light sources to output the optical signal over a length of the optical waveguide.

In accordance with the preceding aspect, wherein the signal generating device comprises one or more self-luminous fibers each of which is configured to output the information signal passively or actively.

In accordance with the preceding aspect, wherein the acquisition and information unit includes a detector including a plurality of detector elements each of which is positioned in a respective one of a plurality of acceptance angles.

In accordance with the preceding aspect, wherein the plurality of acceptance angles overlap with respect to each other.

In accordance with the preceding aspect, wherein the acquisition and information unit is disposed on a garment.

In accordance with the preceding aspect, the apparatus further comprises a current and voltage supply device coupled to the acquisition and information unit.

In accordance with the preceding aspect, wherein the at least one threshold setting is selectable.

In accordance with the preceding aspect, wherein the control device is further configured to adapt the at least one threshold setting based on sensed motion characteristics of the first object.

In accordance with the preceding aspect, wherein the acquisition and information unit includes a plurality of photodiodes arranged horizontally with overlapping acceptance angles or one or more band filters to pass through the signal pulse in a particular wavelength.

In accordance with the preceding aspect, wherein the signal generating device is configured to output the information signal with a quality that is determined in accordance with the detected signal pulse.

In accordance with the preceding aspect, wherein the signal generating device includes a rigid or flexible flat screen display device, a smartphone, a smart watch, or an augmented reality device.

A third aspect of the present disclosure provides an apparatus disposed on an object located in a field of view (FOV) of a LIDAR system. The apparatus comprising: a receiver configured to receive a plurality of first pulses emitted by the LIDAR system; and a radiator configured to be excited by the plurality of first pulses and to emit a plurality of second pulses, wherein the plurality of second pulses indicates object information associated with the object.

In accordance with the preceding aspect, wherein the object information is modulated on the plurality of second pulses.

In accordance with the preceding aspect, wherein the apparatus is a marker.

In accordance with the preceding aspect, wherein the apparatus is a passive marker.

In accordance with the preceding aspect, wherein the passive marker is a fluorescence marker.

In accordance with the preceding aspect, wherein the apparatus is an active marker.

In accordance with the preceding aspect, wherein the receiver of the active marker is a photo-electrical radiation receiver, and the radiator of the active marker is a photo-electrical radiation transmitter.

In accordance with the preceding aspect, wherein a time offset exists between a time when the radiator being excited and a time when the plurality of second pulses being emitted.

Preferred embodiments can be found in the independent and dependent claims and in the entire, disclosure, wherein in the description and representation of the features is not always differentiated in detail between the different claim categories; In any case implicitly, the disclosure is always directed both to the method and to appropriately equipped motor vehicles (LIDAR Sensor Devices) and/or a corresponding computer program product.

### BRIEF DESCRIPTION OF THE DRAWING

The detailed description is described with reference to the accompanying figures. The use of the same reference number in different instances in the description and the figure may indicate a similar or identical item. The drawings are not necessarily to scale, emphasis instead generally being placed upon illustrating the principles of the present disclosure.

In the following description, various embodiments of the present disclosure are described with reference to the following drawings, in which:

FIG. 1 shows schematically an embodiment of the proposed to LIDAR Sensor System, Controlled LIDAR Sensor System and LIDAR Sensor Device;

FIG. 2 is a top view on a typical road traffic situation in a schematic form showing the principles of the disclosure for a system to detect and/or communicate with a traffic participant;

FIG. 3 is a perspective view of a garment as an explanatory second object in a system to detect and/or communicate with a traffic participant according to FIG. 2.

FIG. 4 is a scheme of the disclosed method for a system to detect and/or communicate with a traffic participant.

### DETAILED DESCRIPTION

LIDAR Sensor System and LIDAR Sensor Device

The LIDAR Sensor System according to the present disclosure may be combined with a LIDAR Sensor Device for illumination of an environmental space connected to a light control unit.

The MAR Sensor System may comprise at least one light module. Said one light module has a light source and a driver connected to the light source. The LIDAR Sensor System further has an interface unit, in particular a hardware interface, configured to receive, emit, and/or store data signals. The interface unit may connect to the driver and/or to the light source for controlling the operation state of the driver and/or the operation of the light source.

The light source may be configured to emit radiation in the visible and/or the non-visible spectral range, as for example in the far-red range of the electromagnetic spectrum. It may be configured to emit monochromatic laser light. The light source may be an integral part of the LIDAR Sensor System as well as a remote yet connected element. It may be placed in various geometrical patterns, distance pitches and may be configured for alternating of color or wavelength emission or intensity or beam angle. The LIDAR Sensor System and/or light sources may be mounted such that they are moveable or can be inclined, rotated, tilted etc. The LIDAR Sensor System and/or light source may be configured to be installed inside a LIDAR Sensor Device (e.g. vehicle) or exterior to a LiDAR Sensor Device (e.g. vehicle). In particular, it is possible that the LIDAR light source or selected LIDAR light sources are mounted such or adapted to being automatically controllable, in some implementations remotely, in theft orientation, movement, light emission, light spectrum, sensor etc.

The light source may be selected from the following group or a combination thereof: light emitting diode (LED), super-luminescent laser diode (LD), VSECL laser diode array.

In some embodiments, the LIDAR Sensor System may comprise a sensor, such as a resistive, a capacitive, an inductive, a magnetic:, an optical and; or a chemical sensor. It may comprise a voltage or current sensor. The sensor may connect to the interface unit and/or the driver of the LIDAR light source.

In some embodiments, the LIDAR Sensor System and/or LIDAR Sensor Device comprise a brightness sensor, for example for sensing environmental light conditions in proximity of vehicle objects, such as houses, bridges, sign posts, and the like. It may be used for sensing daylight conditions and the sensed brightness signal may e.g. be used to improve surveillance efficiency and accuracy. That way, it may be enabled to provide the environment with a required amount of light of a predefined wavelength.

In some embodiments, the LIDAR Sensor System and/or LIDAR Sensor Device comprises a sensor for vehicle movement, position and orientation. Such sensor data may allow a better prediction, as to whether the vehicle steering conditions and methods are sufficient.

The LIDAR Sensor System and/or LIDAR Sensor Device may also comprise a presence sensor. This may allow to adapt the emitted light to the presence of another traffic participant including pedestrians in order to provide sufficient illumination, prohibit or minimize eye damage or skin irritation or such due to illumination in harmful or invisible wavelength regions, such as UV or IR. It may also be enabled to provide light of a wavelength that may warn or frighten away unwanted presences, e.g. the presence of animals such as pets or insects.

In some embodiments, the LIDAR Sensor System and/or LIDAR Sensor Device comprises a sensor or multi-sensor for predictive maintenance and/or operation of the LIDAR Sensor System and/or LIDAR Sensor Device failure.

In some embodiments, the LIDAR Sensor System and/or LIDAR Sensor Device comprises an operating hour meter. The operating hour meter may connect to the driver.

The LIDAR Sensor System may comprise one or more actuators for adjusting the environmental surveillance conditions for the LIDAR Sensor Device (e.g. vehicle). For instance, it may comprise actuators that allow adjusting for instance, laser pulse shape, temporal length, rise- and fall times, polarization, laser power, laser type (IR-diode, VCSEL), Field of View (FOV), laser wavelength, beam changing device (MEMS, DMD, DLP, LCD, Fiber), beam and/or sensor aperture, sensor type (RN-diode, APD, SPAD).

While the sensor or actuator has been described as part of the LIDAR Sensor System and/or LIDAR Sensor Device, it is understood, that any sensor or actuator may be an individual element or may form part of a different element of the LIDAR Sensor System. As well, it may be possible to provide an additional sensor or actuator, being configured to perform or performing any of the described activities as individual element or as part of an additional element of the LIDAR Sensor System.

In some embodiments, the LIDAR Sensor System and/or LIDAR Light Device further comprises a light control unit that connects to the interface unit.

The light control unit may be configured to control the at least one light module for operating in at least one of the following operation modes: dimming, pulsed, PWM, boost, irradiation patterns, including illuminating and non-illuminating periods, light communication (including C2C and C2X), synchronization with other elements of the LIDAR Sensor System, such as a second LIDAR Sensor Device.

The interface unit of the LIDAR Sensor System and/or LIDAR Sensor Device may comprise a gateway, such as a wireless gateway, that may connect to the light control unit. It may comprise a beacon, such as a Bluetooth™ beacon.

The interface unit may be configured to connect to other elements of the LIDAR Sensor System, e.g. one or more other LIDAR Sensor Systems and/or LIDAR Sensor Devices and/or to one or more sensors and/or one or more actuators of the LIDAR Sensor System.

The interface unit may be configured to be connected by any wireless or wireline connectivity, including radio and/or optical connectivity.

The LIDAR Sensor System and/or LIDAR Sensor Device may be configured to enable customer-specific and/or vehicle-specific light spectra. The LIDAR Sensor Device may be configured to change the form and/or position and/or orientation of the at least one LIDAR Sensor System. Further, the LIDAR Sensor System and/or LIDAR Sensor Device may be configured to change the light specifications of the light emitted by the light source, such as direction of emission, angle of emission, beam divergence, color, wavelength, and intensity as well as other characteristics like laser pulse shape, temporal length, rise- and fall times, polarization, pulse synchronization, pulse synchronization, laser power, laser type (IR-diode, VOSEL), Field of View (FOV), laser wavelength, beam changing device (MEMS, DMD, DLP, LCD, Fiber), beam and/or sensor aperture, sensor type (PN-diode; APD, SPAD).

In some embodiments, the LIDAR Sensor System and/or LIDAR Sensor Device may comprise a data processing unit. The data processing unit may connect to the LIDAR light driver and/or to the interface unit. It may be configured for data processing, for data and/or signal conversion and/or data storage. The data processing unit may advantageously be provided for communication with local, network-based or web-based platforms, data sources or providers, in order to transmit, store or collect relevant information on the light module, the road to be travelled, or other aspects connected with the LIDAR Sensor System and/or LIDAR Sensor Device.

In some embodiments, the LIDAR Sensor Device can encompass one or many MAR Sensor Systems that themselves can be comprised of infrared or visible light emitting modules, photoelectric sensors, optical components, interfaces for data communication, actuators, like MEMS mirror systems, computing and data storage devices, software and software databank, communication systems for communication with IoT, edge or cloud systems.

The LIDAR Sensor System and/or LIDAR Sensor Device can further include light emitting and light sensing elements that can be used for illumination purposes, like road lighting, or for data communication purposes, for example car-to-car, car-to-environment (for example drones, pedestrian, traffic signs, traffic posts etc.)

The LIDAR Sensor Device can further comprise one or more LIDAR Sensor Systems as well as other sensor systems, like optical camera sensor systems (CCD; CMOS), RADAR sensing system, and ultrasonic sensing systems.

The LIDAR Sensor Device can be functionally designed as vehicle headlight, rear light, side light, daytime running light (DRL), corner light etc. and comprise LIDAR sensing functions as well as visible illuminating and signaling functions.

The LIDAR Sensor System may further comprise a control unit (Controlled LIDAR Sensor System). The control unit may be configured for operating a management system. It is configured to connect to one or more LIDAR Sensor Systems and/or LIDAR Sensor Devices. It may connect to a data bus. The data bus may be configured to connect to an interface unit of an LIDAR Sensor Device. As part of the management system, the control unit may be configured for controlling an operating state of the LIDAR Sensor System and/or LIDAR Sensor Device.

The LIDAR Sensor Management System may comprise a light control system which may comprise any of the following elements: monitoring and/or controlling the status of the at least one LIDAR Sensor System and/or LIDAR Sensor Device, monitoring and/or controlling the use of the at least one LIDAR Sensor System and/or LIDAR Sensor Device, scheduling the lighting of the at least one LIDAR Sensor System and/or LIDAR Sensor Device, adjusting the light spectrum of the at least one LIDAR Sensor System and/or LIDAR Sensor Device, defining the light spectrum of the at least one LIDAR Sensor System and/or LIDAR Sensor Device, monitoring and/or controlling the use of at least one sensor of the at least one LIDAR Sensor System and/or LIDAR Sensor Device.

In some embodiments, the method for LIDAR Sensor System can be configured and designed to select, operate and control, based on internal or external data input, laser power, pulse shapes, pulse length, measurement time windows, wavelength, single wavelength or multiple wavelength approach, day and night settings, sensor type, sensor fusion, as well as laser safety functions according to relevant safety regulations.

The method for LIDAR Sensor Management System can be configured to initiate data encryption, data decryption and data communication protocols.

LIDAR Sensor System. Controlled LIDAR Sensor System. LIDAR Sensor Management System and Software

In a Controlled LIDAR Sensor System according to the present disclosure, the computing device may be locally based, network based, and/or cloud-based. That means, the computing may be performed in the Controlled LIDAR Sensor System or on any directly or indirectly connected entities. In the latter case, the Controlled LIDAR Sensor System is provided with some connecting means, which allow establishment of at least a data connection with such connected entities.

In some embodiments, the Controlled LIDAR Sensor System comprises a LIDAR Sensor Management System connected to the at least one hardware interface. The LIDAR Sensor Management System may comprise one or more actuators for adjusting the surveillance conditions for the environment. Surveillance conditions may, for instance, be vehicle speed, vehicle road density, vehicle distance to other objects, object type, object classification, emergency situations, weather conditions, day or night conditions, day or night time, vehicle and environmental temperatures, and driver biofeedback signals.

The present disclosure further comprises an LIDAR Sensor Management Software. The present disclosure further comprises a data storage device with the LIDAR Sensor Management Software, wherein the data storage device is enabled to run the LIDAR Sensor Management Software. The data storage device may either comprise be a hard disk, a RAM, or other common data storage utilities such as USB storage devices, CDs, DVDs and similar.

The LIDAR Sensor System, in particular the LIDAR Sensor Management Software, may be configured to control the steering of Automatically Guided Vehicles (AGV).

In some embodiments, the computing device is configured to perform the LIDAR Sensor Management Software.

The LIDAR Sensor Management Software may comprise any member selected from the following group or a combination thereof: software rules for adjusting light to outside conditions, adjusting the light intensity of the at least one LIDAR Sensor System and/or LIDAR Sensor Device to environmental conditions, adjusting the light spectrum of the at least one LIDAR Sensor System and/or LIDAR Sensor Device to environmental conditions, adjusting the light spectrum of the at least one LIDAR Sensor System and/or LIDAR Sensor Device to traffic density conditions, adjusting the light spectrum of the at least one LIDAR Sensor System and/or LIDAR Sensor Device according to customer specification or legal requirements.

According to some embodiments, the Controlled LIDAR Sensor System further comprises a feedback system connected to the at least one hardware interface. The feedback system may comprise one or more sensors for monitoring the state of surveillance for which the Controlled LIDAR Sensor System is provided. The state of surveillance may for example, be assessed by at least one of the following: road accidents, required driver interaction, Signal-to-Noise ratios, driver biofeedback signals, close encounters, fuel consumption, and battery status.

The Controlled LIDAR Sensor System may further comprise a feedback software.

The feedback software may in some embodiments comprise algorithms for vehicle (LIDAR Sensor Device) steering assessment on the basis of the data of the sensors.

The feedback software of the Controlled LIDAR Sensor System may in some embodiments comprise algorithms for deriving surveillance strategies and/or lighting strategies on the basis of the data of the sensors.

The feedback software of the Controlled LIDAR Sensor System may in some embodiments of the present disclosure comprise LIDAR lighting schedules and characteristics depending on any member selected from the following group or a combination thereof: road accidents, required driver interaction, Signal-to-Noise ratios, driver biofeedback signals, close encounters, road warnings, fuel consumption, battery status, other autonomously driving vehicles.

The feedback software may be configured to provide instructions to the LIDAR Sensor Management Software for adapting the surveillance conditions of the environment autonomously.

The feedback software may comprise algorithms for interpreting sensor data and suggesting corrective actions to the LIDAR Sensor Management Software.

In some embodiments of the LIDAR Sensor System, the instructions to the LIDAR Sensor Management Software are based on measured values and/or data of any member selected from the following group or a combination thereof: vehicle (LIDAR Sensor Device) speed, distance, density, vehicle specification and class.

The LIDAR Sensor System therefore may have a data interface to receive the measured values and/or data. The data interface may be provided for wire-bound transmission or wireless transmission. In particular, it is possible that the measured values or the data are received from an intermediate storage, such as a cloud-based, web-based, network-based or local type storage unit.

Further, the sensors for sensing environmental conditions may be connected with or interconnected by means of cloud-based services, often also referred to as Internet of Things.

In some embodiments, the Controlled LIDAR Sensor System comprises a software user interface (UI), particularly a graphical user interface (GUI). The software user interface may be provided for the light control software and/or the LIDAR Sensor Management Software and/or the feedback software.

The software user interface (UI) may further comprise a data communication and means for data communication for an output device, such as an augmented and/or virtual reality display.

The user interface may be implemented as an application for a mobile device, such as a smartphone, a tablet, a mobile computer or similar devices.

The Controlled LIDAR Sensor System may further comprise an application programming Interface (API) for controlling the LIDAR Sensing System by third parties and/or for third party data integration, for example road or traffic conditions, street fares, energy prices, weather data, GPS.

In some embodiments, the Controlled LIDAR Sensor System comprises a software platform for providing at least one of surveillance data, vehicle (LIDAR Sensor Device) status, driving strategies, and emitted sensing light.

In some embodiments, the LIDAR Sensor System and/or the Controlled LIDAR Sensor System can include infrared or visible light emitting modules, photoelectric sensors, optical components, interfaces for data communication, and actuators, like MEMS mirror systems, a computing and data storage device, a software and software databank, a communication system for communication with IoT, edge or cloud systems.

The LIDAR Sensor System and/or the Controlled LIDAR Sensor System can include light emitting and light sensing elements that can be used for illumination or signaling purposes, like road lighting, or for data communication purposes, for example car-to-car, car-to-environment.

In some embodiments, the LIDAR Sensor System and/or the Controlled LIDAR Sensor System may be installed inside the driver cabin in order to perform driver monitoring functionalities, such as occupancy-detection, eye-tracking, face recognition, drowsiness detection, access authorization, gesture control, etc.) and/or to communicate with a Head-up-Display HUD).

The software platform may cumulate data from one's own or other vehicles (LIDAR Sensor Devices) to train machine learning algorithms for improving surveillance and car steering strategies.

The Controlled LIDAR Sensor System may also comprise a plurality of LIDAR Sensor Systems arranged in adjustable groups.

The present disclosure further refers to a vehicle (LIDAR Sensor Device) with at least one LIDAR Sensor System. The vehicle may be planned and build particularly for integration of the LIDAR Sensor System. However, it is also possible, that the Controlled LIDAR Sensor System was integrated in a pre-existing vehicle. According to the present disclosure, both cases as well as a combination of these cases shall be referred to.

Method for a LIDAR Sensor System

According to yet another aspect of the present disclosure, a method for a LIDAR Sensor System is provided, which comprises at least one LIDAR Sensor System. The method may comprise the steps of controlling the light emitted by the at least one LIDAR Sensor System by providing light control data to the hardware interface of the Controlled LIDAR Sensor System and/or sensing the sensors and/or controlling the actuators of the Controlled LIDAR Sensor System via the LIDAR Sensor Management System.

According to yet another aspect of the present disclosure, the method for LIDAR Sensor System can be configured and designed to select, operate and control, based on internal or external data input, laser power, pulse shapes, pulse length, measurement time windows, wavelength, single wavelength or multiple wavelength approach, day and night settings, sensor type, sensor fusion, as well as laser safety functions according to relevant safety regulations.

The method according to the present disclosure may further comprise the step of generating light control data for adjusting the light of the at least one LIDAR Sensor System to environmental conditions.

In some embodiments, the light control data is generated by using data provided by the daylight or night vision sensor.

According to some embodiments, the light control data is generated by using data provided by a weather or traffic control station.

The light control data may also be generated by using data provided by a utility company in some embodiments.

Advantageously, the data may be gained from one data source, whereas that one data source may be connected, e.g. by means of Internet of Things devices, to those devices, That way, data may be pre-analyzed before being released to the LIDAR Sensor System, missing data could be identified, and in further advantageous developments, specific pre-defined data could also be supported or replaced by “best-guess” values of a machine learning software.

In some embodiments, the method further comprises the step of using the light of the at least one LIDAR Sensor Device for example during the time of day or night when traffic conditions are the best. Of course, other conditions for the application of the light may also be considered.

In some embodiments, the method may comprise a step of switching off the light of the at least one LIDAR Sensor System depending on a predetermined condition. Such condition may for instance occur, if the vehicle (MAR Sensor Device) speed or a distance to another traffic object is lower than a pre-defined or required safety distance or safety condition.

The method may also comprise the step of pushing notifications to the user interface in case of risks or fail functions and vehicle health status.

In some embodiments, the method comprises analyzing sensor data for deducing traffic density and vehicle movement.

The LIDAR Sensor System features may be adjusted or triggered by way of a user interface or other user feedback data. The adjustment may further be triggered by way of a machine learning process, as far as the characteristics, which are to be improved or optimized are accessible by sensors. It is also possible that individual users adjust the surveillance conditions and or further surveillance parameters to individual needs or desires.

The method may also comprise the step of uploading LIDAR sensing conditions to a software platform and/or downloading sensing conditions from a software platform.

In at least one embodiment, the method comprises a step of logging performance data to an LIDAR sensing note book.

The data cumulated in the Controlled LIDAR Sensor System may, in a step of the method, be analyzed in order to directly or indirectly determine maintenance periods of the LIDAR Sensor System, expected failure of system components or such.

According to another aspect, the present disclosure comprises a computer program product comprising a plurality of program instructions, which when executed by a computer system of a LIDAR Sensor System, cause the Controlled LIDAR Sensor System to execute the method according to the present disclosure. The disclosure further comprises a data storage device.

Yet another aspect of the present disclosure refers to a data storage device with a computer program adapted to execute at least one of a method for a LIDAR Sensor System or a LIDAR Sensor Device.

Autonomously driving vehicles need sensing methods that detect objects and map their distances in a fast and reliable manner. Light detection and ranging (MAR), sometimes called Laser Detection and Ranging (LADAR), Time of Right measurement device (TOF), Laser Scanners or Laser Radar—is a sensing method that detects objects and maps their distances. The technology works by illuminating a target with an optical pulse and measuring the characteristics of the reflected return signal. The width of the optical-pulse can range from a few nanoseconds to several microseconds.

In order to steer and guide autonomous cars in a complex driving environment, it is adamant to equip vehicles with fast and reliable sensing technologies that provide high-resolution, three-dimensional information (Data Cloud) about the surrounding environment thus enabling proper vehicle control by using on-board or cloud-based computer systems.

For distance and speed measurement, a light-detection-and-ranging LIDAR Sensor Systems can be used. With LIDAR Sensor Systems, it is possible to quickly scan the environment and detect speed and direction of movement of individual objects (vehicles, pedestrians, static objects). LIDAR Sensor Systems are used, for example, in partially autonomous vehicles or fully autonomously driving prototypes, as well as in aircraft and drones. A high-resolution LIDAR Sensor System emits a (mostly infrared) laser beam, and further uses lenses, mirrors or micro-mirror systems, as well as suited sensor devices.

The disclosure relates to a LIDAR Sensor System for environment detection, wherein the LIDAR Sensor System is designed to carry out repeated measurements for detecting the environment, wherein the LIDAR Sensor System has an emitting unit (First LIDAR Sensing System) which is designed to perform a measurement with at least one laser pulse and wherein the LIDAR system has a detection unit (Second LIDAR Sensing Unit); which is designed to detect an object-reflected laser pulse during a measurement time window. Furthermore, the LIDAR system has a control device (LIDAR Data Processing System/Control and Communication System/LIDAR Sensor Management System), which is designed, in the event that at least one reflected beam component is detected, to associate the detected beam component on the basis of a predetermined assignment with a solid angle range from which the beam component originates. The disclosure also includes a method for operating a LIDAR Sensor System.

The distance measurement in question is based on a transit time measurement of emitted electromagnetic pulses. The electromagnetic spectrum should range from the ultraviolet via the visible to the infrared, including violet and blue radiation in the range from 405 to 480 nm. If these hit an object, the pulse is proportionately reflected back to the distance-measuring unit and can be recorded as an echo pulse with a suitable sensor. If the emission of the pulse takes place at a time t0 and the echo pulse is detected at a later time t1, the distance d to the reflecting surface of the object over the transit time ΔtA=t1−t0 can be determined according Eq. 1.

d=ΔtA c/2 Eq. 1

Since these are electromagnetic pulses, c is the value of the speed of light. In the context of this disclosure, the word electromagnetic comprises the entire electromagnetic spectrum, thus including the ultraviolet, visible and infrared spectrum range.

The LIDAR method is usefully working with light pulses which, for example, using semiconductor laser diodes having a wavelength between about 850 nm to about 1600 nm, which have a FWHM pulse width of 1 ns to 100 ns (FWHM=Full Width at Half Maximum). Also conceivable in general are wavelengths up to, in particular approximately, 8100 nm.

Furthermore, each light pulse is typically associated with a measurement time window, which begins with the emission of the measurement light pulse. If objects that are very far away are to be detectable by a measurement, such as, for example, objects at a distance of 300 meters and farther, this measurement time window, within which it is checked whether at least one reflected beam component has been received, must last at least two microseconds. In addition, such measuring time windows typically have a temporal distance from each other.

The use of LIDAR sensors is now increasingly used in the automotive sector, Correspondingly, LIDAR sensors are increasingly installed in motor vehicles.

The disclosure also relates to a method for operating a LIDAR Sensor System arrangement comprising a First LIDAR Sensor System with a first LIDAR sensor and at least one Second LIDAR Sensor System with a second LIDAR sensor, wherein the first LIDAR sensor and the second LIDAR sensor repeatedly perform respective measurements, wherein the measurements of the first LIDAR Sensor are performed in respective first measurement time windows, at the beginning of which a first measurement beam is emitted by the first LIDAR sensor and it is checked whether at least one reflected beam component of the first measurement beam is detected within the respective first measurement time window. Furthermore, the measurements of the at least one second LIDAR sensor are performed in the respective second measurement time windows, at the beginning of which a second measurement beam is emitted by the at least one second LIDAR sensor, and it is checked whether within the respective second measurement time window at least one reflected beam portion of the second measuring beam is detected. The disclosure also includes a LIDAR Sensor System arrangement with a first LIDAR sensor and at least one second LIDAR sensor.

A LIDAR (light detection and ranging) Sensor System is to be understood in particular as meaning a system which, in addition to one or more emitters for emitting light beams, for example in pulsed form, and a detector for detecting any reflected beam components, may have further devices, for example optical elements such as lenses and/or a MEMS mirror.

The oscillating mirrors or micro-mirrors of the MEMS (Micro-Electro-Mechanical System) system, in some embodiments in cooperation with a remotely located optical system, allow a field of view to be scanned in a horizontal angular range of e.g. 60° or 120″ and in a vertical angular range of e.g. 30°. The receiver unit or the sensor can measure the incident radiation without spatial resolution. The receiver unit can also be spatial angle resolution measurement device. The receiver unit or sensor may comprise a photodiode, e.g. an avalanche photo diode (APD) or a single photon avalanche diode (SPAD), a PIN diode or a photomultiplier. Objects can be detected, for example, at a distance of up to 60 m, up to 300 m or up to 600 m using the LIDAR system. A range of 300 m corresponds to a signal path of 600 m, from which, for example, a measuring time window or a measuring duration of 2 μs can result.

As already described, optical reflection elements in a LIDAR Sensor System may include micro-electrical mirror systems (MEMS) and/or digital mirrors (DMD) and/or digital light processing elements (DLP) and/or a galvo-scanner for control of the emitted laser beam pulses and/or reflection of an object-back-scattered laser pulses onto a sensor surface. Advantageously, a plurality of mirrors is provided. These may particularly be arranged in some implementations in the manner of a matrix. The mirrors may be individually and separately, independently of each other rotatable or movable.

The individual mirrors can each be part of a so-called micro mirror unit or “Digital Micro-Mirror Device” (DMD). A DMD can have a multiplicity of mirrors, in particular micro-mirrors, which can be rotated at high frequency between at least two positions. Each mirror can be individually adjustable in its angle and can have at least two stable positions, or with other words, in particular stable, final states, between which it can alternate. The number of mirrors can correspond to the resolution of a projected image, wherein a respective mirror can represent a light pixel on the area to be irradiated. A “Digital Micro-Mirror Device” is a micro-electromechanical component for the dynamic modulation of light.

Thus, the DMD can for example provide suited illumination for a vehicle low and/or a high beam. Furthermore, the DMD may also serve projection light for projecting images, logos, and information on a surface, such as a street or surrounding object. The mirrors or the DMD can be designed as a micro-electromechanical system (MEMS). A movement of the respective mirror can be caused, for example, by energizing the MEMS. Such micro-mirror arrays are available, for example, from Texas Instruments. The micro-mirrors are in particular arranged like a matrix, e.g. for example, in an array of 854×480 micro-mirrors, as in the DLP3030-01 0.3-inch DMP mirror system optimized for automotive applications by Texas Instruments, or a 1920×1080 micro-mirror system designed for home projection applications 4096×2160 Micro-mirror system designed for 4K cinema projection applications, but also usable in a vehicle application. The position of the micro-mirrors is, in particular, individually adjustable, for example with a clock rate of up to 32 kHz, so that predetermined light patterns can be coupled out of the headlamp by corresponding adjustment of the micro-mirrors.

In some embodiments, the used MEMS arrangement may be provided as a 1D or 2D MEMS arrangement. In a 1D MEMS, the movement of an individual mirror takes place in a translatory or rotational manner about an axis. In 2D MEMS, the individual mirror is gimballed and oscillates about two axes, whereby the two axes can be individually employed so that the amplitude of each vibration can be adjusted and controlled independently of the other.

Furthermore, a beam radiation from the light source can be deflection through a structure with at least one liquid crystal element, wherein one molecular orientation of the at least one liquid crystal element is adjustable by means of an electric field. The structure through which the radiation to be aligned is guided can comprise at least two sheet-like elements coated with electrically conductive and transparent coating material. The plate elements are in some embodiments transparent and spaced apart from each other in parallel. The transparency of the plate elements and the electrically conductive coating material allows transmission of the radiation. The electrically conductive and transparent coating material can at least partially or completely made of a material with a high electrical conductivity or a small electrical resistance such as indium tin oxide (ITO) and/or of a material with a low electrical conductivity or a large electrical resistance such as poly-3,4-ethylenedioxythiophene (PEDOT).

The generated electric field can be adjustable in its strength. The electric field can be adjustable in particular by applying an electrical voltage to the coating material or the coatings of the plate elements. Depending on the size or height of the applied electrical voltages on the coating materials or coatings of the plate elements formed as described above, differently sized potential differences and thus a different electrical field are formed between the coating materials or coatings.

Depending on the strength of the electric field, that is, depending on the strength of the voltages applied to the coatings, the molecules of the liquid crystal elements may align with the field lines of the electric field.

Due to the differently oriented liquid crystal elements within the structure, different refractive indices can be achieved. As a result, the radiation passing through the structure, depending on the molecular orientation, moves at different speeds through the liquid crystal elements located between the plate elements. Overall, the liquid crystal elements located between the plate elements have the function of a prism, which can deflect or direct incident radiation. As a result, with a correspondingly applied voltage to the electrically conductive coatings of the plate elements, the radiation passing through the structure can be oriented or deflected, whereby the deflection angle can be controlled and varied by the level of the applied voltage.

Furthermore, a combination of white or colored light sources and infrared laser light sources is possible, in which the light source is followed by an adaptive mirror arrangement, via which radiation emitted by both light sources can be steered or modulated, a sensor system being used for the infrared light source intended for environmental detection. The advantage of such an arrangement is that the two light systems and the sensor system use a common adaptive mirror arrangement. It is therefore not necessary to provide for the light system and the sensor system each have their own mirror arrangement. Due to the high degree of integration space, weight and in is particular costs can be reduced.

In LIDAR systems, differently designed transmitters and receiver concepts are also known in order to be able to record the distance information in different spatial directions. Based on this, a two-dimensional image of the environment is then generated, which contains the complete three-dimensional coordinates for each resolved spatial point. The different LIDAR topologies can be abstractly distinguished based on how the image resolution is displayed. Namely, the resolution can be represented either exclusively by an angle-sensitive detector, an angle-sensitive emitter, or a combination of both. A LIDAR system, which generates its resolution exclusively by means of the detector, is called a Flash LIDAR. It includes of an emitter, which illuminates as homogeneously as possible the entire field of vision. In contrast, the detector in this case includes of a plurality of individually readable and arranged in a matrix segments or pixels. Each of these pixels is correspondingly assigned a solid angle range. If light is received in a certain pixel, then the light is correspondingly derived from the solid angle region assigned to this pixel. In contrast to this, a raster or scanning LIDAR has an emitter which emits the measuring pulses selectively and in particular temporally sequentially in different spatial directions. Here a single sensor segment is sufficient as a detector. If, in this case, light is received by the detector in a specific measuring time window, then this light comes from a solid angle range into which the light was emitted by the emitter in the same measuring time window.

To improve Signal-to-Noise Ratio (SNR), a plurality of the above-described measurements or single-pulse measurements can be netted or combined with each other in a LIDAR Sensor System, for example to improve the signal-to-noise ratio by averaging the determined measured values.

The radiation emitted by the light source is in some embodiments infrared (IR) radiation emitted by a laser diode in a wavelength range of 600 nm to 850 nm. However, wavelengths up to 1064 nm, up to 1600 nm, up to 5600 nm or up to 8100 nm are also possible. The radiation of the laser diode can be emitted in a pulse-like manner with a frequency between 1 kHz and 1 MHz, in some implementations with a frequency between 10 kHz and 100 kHz. The laser pulse duration may be between 0.1 ns and 100 ns, in some implementations between 1 ns and 2 ns. As a type of the IR radiation emitting laser diode, a VCSEL (Vertical Cavity Surface Emitting Laser) can be used, which emits radiation with a radiation power in the “milliwatt” range. However, it is also possible to use a VECSEL (Vertical External Cavity Surface Emitting Laser), which can be operated with high pulse powers in the wattage range. Both the VCSEL and the VECSEL may be in the form of an array, e.g. 15)(20 or 20×20 laser diodes may be arranged so that the summed radiation power can be several hundred watts. If the lasers pulse simultaneously in an array arrangement, the largest summed radiation powers can be achieved. The emitter units may differ, for example, in their wavelengths of the respective emitted radiation. If the receiver unit is then also configured to be wavelength-sensitive, the pulses can also be differentiated according to their wavelength.

Other embodiments are directed to data analysis and data usage and are described in Chapter “Data Usage”.

It is an object of the disclosure to propose improved components for a LIDAR Sensor System and/or to propose improved solutions for a LIDAR Sensor System and/or for a LIDAR Sensor Device and/or to propose improved methods for a LIDAR Sensor System and/or for a LIDAR Sensor Device.

The object is achieved according to the features of the independent claims. Further aspects of the disclosure are given in the dependent claims and the following description.

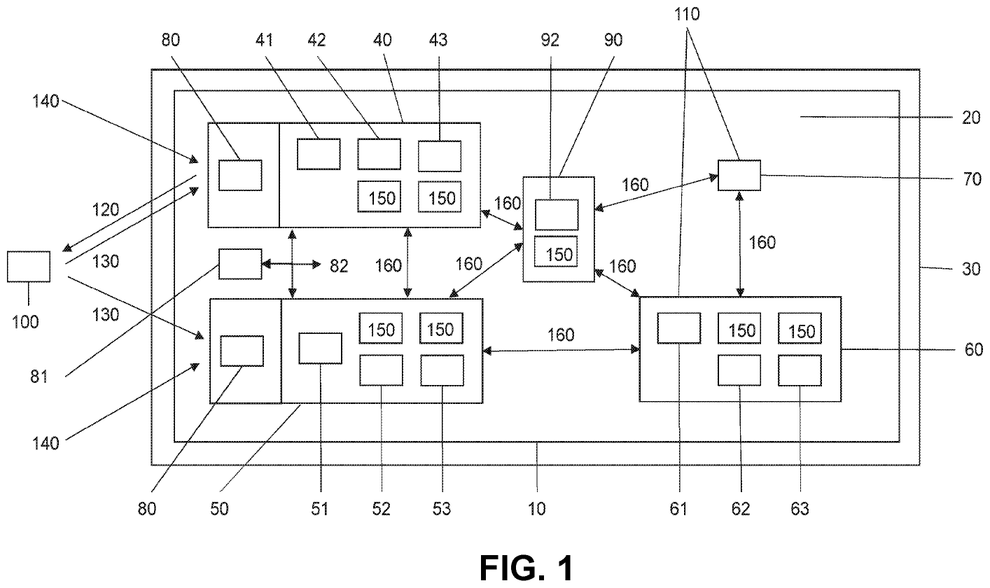

FIG. 1 shows schematically an embodiment of the proposed LIDAR Sensor System, Controlled LIDAR Sensor System and LIDAR Sensor Device.

The LIDAR Sensor System 10 comprises a First LIDAR Sensing System 40 that may comprise a Light Source 42 configured to emit electro-magnetic or other radiation 120, in particular a continuous-wave or pulsed laser radiation in the blue and/or infrared wavelength range, a Light Source Controller 43 and related Software, Beam Steering and Modulation Devices 41, in particular light steering and reflection devices, for example Micro-Mechanical Mirror Systems (MEMS), with a related control unit 150, Optical components 80, for example lenses and/or holographic elements, a LIDAR Sensor Management System 90 configured to manage input and output data that are required for the proper operation of the First LIDAR Sensing System 40.

The First LIDAR Sensing System 40 may be connected to other LIDAR Sensor System devices, for example to a Control and Communication System 70 that is configured to manage input and output data that are required for the proper operation of the First LIDAR Sensor System 40.

The LIDAR Sensor System 10 may include a Second LIDAR Sensing System 50 that is configured to receive and measure electromagnetic or other radiation, using a variety of Sensors 52 and Sensor Controller 53.

The Second LiDAR Sensing System may comprise Detection Optics 82, as well as Actuators for Beam Steering and Control 51.

The LIDAR Sensor System 10 may further comprise a LIDAR Data Processing System 60 that performs Signal Processing 61, Data Analysis and Computing 62, Sensor Fusion and other sensing Functions 63.

The LIDAR Sensor System 10 may further comprise a Control and Communication System 70 that receives and outputs a variety of signal and control data 160 and serves as a Gateway between various functions and devices of the LIDAR Sensor System 10.

The LIDAR Sensor System 10 may further comprise one or many Camera Systems 81, either stand-alone or combined with another Lidar Sensor System 10 component or embedded into another Lidar Sensor System 10 component, and data-connected to various other devices like to components of the Second LIDAR Sensing System 50 or to components of the LIDAR Data Processing System 60 or to the Control and Communication System 70.

The LIDAR Sensor System 10 may be integrated or embedded into a LIDAR Sensor Device 30, for example a housing, a vehicle, a vehicle headlight.

The Controlled LIDAR Sensor System 20 is configured to control the LIDAR Sensor System 10 and its various components and devices, and performs or at least assists in the navigation of the LIDAR Sensor Device 30. The Controlled LIDAR Sensor System 20 may be further configured to communicate for example with another vehicle or a communication networks and thus assists in navigating the LIDAR Sensor Device 30.

As explained above, the LIDAR Sensor System 10 is configured to emit electro-magnetic or other radiation in order to probe the environment 100 for other objects, like cars, pedestrians, road signs, and road obstacles. The L1 DAR Sensor System 10 is further configured to receive and measure electromagnetic or other types of object-reflected or object-emitted radiation 130, but also other wanted or unwanted electromagnetic radiation 140, in order to generate signals 110 that can be used for the environmental mapping process, usually generating a point cloud that is representative of the detected objects.

Various components of the Controlled LIDAR Sensor System 20 use Other Components or Software 150 to accomplish signal recognition and processing as well as signal analysis. This process may include the use of signal information that come from other sensor devices.

### Chapter “Data Usage”

It is advantageous for better object recognition if the object located in the field of view (FOV) is provided with a marker. This marker is excited or activated by the pulses of the distance measuring unit (LIDAR Sensor System) and then emits a marker radiation. In this marker radiation, object information for the detection of the object is deposited. The marker radiation is then detected by a radiation detector, which may or may not be part of the distance measuring unit of a LIDAR Sensor Device, and the object information is assigned to the object.

The distance measuring unit can be integrated into a LIDAR Sensor Device (e.g. motor vehicle), in particular to support a partially or fully autonomous driving function. The object provided with the marker may be, for example, another road user, such as another motor vehicle or a pedestrian or cyclist, but also, for example, a road sign or the like may be provided with the marker, or a bridge with a certain maximum permissible load capacity, or a passage with a certain maximum permissible height.

As soon as the object is located in the object field, i.e. in the field of view (FOV), of the distance measuring unit, the marker is excited or activated in some implementations by the electromagnetic distance measuring radiation and in turn emits the marker radiation. This is detected by the radiation detector, which in this example is part of the motor vehicle (which has the emitting distance measuring unit), and an evaluation unit of the motor vehicle can associate the object information with the object. The object can be assigned to a specific object class, which can be displayed to the vehicle driver or taken into account internally in the course of the partially or fully autonomous driving function, Depending on whether it is, for example, a pedestrian at the roadside or a lamppost, the driving strategy can be adapted accordingly (for example greater safety distance in the case of the pedestrian).

By contrast, with the object information stored or embedded in the marker radiation, a reliable classification is possible if objects which fall into different classes of objects are provided with markers which differ in the respective object information stored in the marker radiation. For example, in comparison to the above-mentioned image evaluation methods, the markers can shorten the recognition times. Other object recognition methods, such as, for example, the evaluation of point clouds, are of course still possible, the marker-based recognition can also represent an advantageous supplement.

The way in which the object information is evaluated or derived from the detector signal of the radiation detector or read out can also depend in detail on the structure of the radiation detector itself. If the object information is, for example, frequency-coded, i.e. emit markers with different wavelengths assigned to different object classes, an assignment to the respective marker can already be created by a corresponding filtering of a respective sensor surface, With a respective sensor surface, the respective marker radiation can then only be detected if it has the “suitable” wavelength, namely passes through the filter onto the sensor surface. In that regard, the fact that a detection signal is output at all can indicate that a certain marker is emitting, that is, whose object information is present. On the other hand, however, the object information of the marker radiation can also be modulated, for example (see below in detail), so it can then be read out, for example, by a corresponding signal processing.

As already mentioned above, the marker radiation emitted by the marker (M) is different from any distance measuring radiation which is merely reflected at a Purely Reflective Marker (MPR). Therefore, in contrast to a purely reflected distance measurement radiation that allows information processing with respect to the location or the position of the marker in the object space, the emitted marker (M) radiation contains additional or supplemental information usable for quick and reliable object detection. The marker (M) radiation may differ in its frequency (wavelength) from the employed distance measuring radiation, alternatively or additionally, the object information may be modulated on the marker (M) radiation.

In a preferred embodiment, the marker (M) is a passive marker (PM). This emits the passive marker radiation (MPRA) upon excitation with the distance measuring radiation, for example due to photo-physical processes in the marker material. The marker radiation (MPRA) has in some embodiments a different wavelength than the distance measuring radiation, wherein the wavelength difference may result as an energy difference between different states of occupation. In general, the marker radiation (MPRA) can have a higher energy than the distance measurement radiation (so-called up-conversion), i.e. have a shorter wavelength. In some embodiments, in a down-conversion process the marker radiation (MPRA) has a lower energy and, accordingly, a longer wavelength than the distance measuring radiation.

In a preferred embodiment, the passive marker is a fluorescence marker (in general, however, a phosphorescence marker would also be conceivable, for example). It can be particularly advantageous to use nano-scale quantum dots (for example from CdTe, ZnS, ZnSe, o ZnO), because their emission properties are easily adjustable, that is to say that specific wavelengths can be defined. This also makes it possible to determine a best wavelength for a particular object class.

In another preferred embodiment, the marker is an active marker (MA), This has a photoelectrical radiation receiver and a photo-electrical radiation transmitter, the latter emitting the active marker radiation

(MAR) upon activation of the marker by irradiation of the radiation receiver with the distance measuring radiation. The receiver can be, for example, a photodiode, as a transmitter, for example, a light-emitting diode (LED) can be provided. An LED typically emits relatively wide-anale (usually lambertsch), which may be advantageous in that then the probability is high that a portion of the radiation falls on the radiation detector (of the distance measuring system).

A corresponding active marker (MA) may further include, for example, a driver electronics for the radiation transmitter and/or also signal evaluation and logic functions. The transmitter can, for example, be powered by an integrated energy source (battery, disposable or rechargeable). Depending on the location or application, transmitter and receiver, and if available other components, may be assembled and housed together. Alternatively or additionally, however, a receiver can also be assigned to, for example, one or more decentralized transmitters.

The marker (MA, MP) may, for example, be integrated into a garment, such as a jacket. The garment as a whole can then be equipped, for example, with several markers which either function independently of one another as decentralized units (in some embodiments housed separately) or share certain functionalities with one another (e.g. the power supply and/or the receiver or a certain logic, etc.). Irrespective of this in detail, the present approach, that is to say the marking by means of marker radiation, can even make extensive differentiation possible in that, for example, not the entire item of clothing is provided with the same object information. Related to the person wearing the garment then, for example, arms and/or legs other than the torso may be marked, which may open up further evaluation possibilities. On the other hand, however, it may also be preferred that, as soon as an object is provided with a plurality of markers, they carry the same object information, in particular of identical construction.

In a preferred embodiment, the marker radiation of the active marker (MA) modulates the object information, Though an exclusively wavelength-coded back-signal may be used (Passive Marker MP) with benefit, the modulation of the active (MA) marker radiation can, for example, help to increase the transferable wealth of information. For example, additional data on position and/or movement trajectories may be underlaid. Additionally or alternatively, the modulation may be combined with wavelength coding. The distance measuring radiation and the modulated marker radiation may have in some embodiments the same wavelength. Insofar as spectral intensity distributions are generally compared in this case (that is to say of “the same” or “different” wavelengths), this concerns a comparison of the dominant wavelengths, that is to say that this does not imply discrete spectra (which are possible, but not mandatory).

The object information can be stored, for example, via an amplitude modulation. The marker radiation can also be emitted as a continuous signal, the information then results from the variation of its amplitude over time. In general, the information can be transmitted with the modulation, for example, Morse code-like, it can be used based on common communication standards or a separate protocol can be defined.

In a preferred embodiment, the marker radiation is emitted as a discrete-time signal, that is, the information is stored in a pulse sequence, in this case, a combination with an amplitude modulation is generally possible, it is in some implementations an alternative. The information can then result, in particular, from the pulse sequence, that is, its number and/or the time offset between the individual pulses.

As already mentioned, the marker radiation in a preferred embodiment has at least one spectral overlap with the distance measurement radiation, that is, the intensity distributions have at least one common subset. In some embodiments, it may be radiation of the same wavelength. This can result in an advantageous integration to the effect that the detector with which the marker radiation is received is part of the distance measuring unit. The same detector then detects the marker radiation on the one hand and the distance measurement radiation reflected back from the object space on the other hand.

A further embodiment relates to a situation in which a part of the distance measurement radiation is reflected on the object as an echo pulse back to the distance measuring unit. The active marker then emits the marker radiation in a preferred embodiment such that this echo pulse is amplified; in other words, the apparent reflectivity is increased. Alternatively or in addition to the coding of the object category, the detection range of the emitting distance measuring unit can therefore also be increased.

It is described a method and a distance measuring system for detecting an object located in an object space in which method a distance measuring pulse is emitted into the object space with a signal delay-based distance measuring unit, wherein the object is provided with a marker which, upon the action of the distance measuring pulse, generates an electromagnetic marker, Radiation emitted in which an object information for object detection is stored, wherein the marker radiation detected with an electric radiation detector and the object information for object recognition is assigned to the object. The marker radiation may differ in its spectral properties from the distance measuring radiation, since the object information can be wavelength-coded, Between the activation by irradiation and the emission of the radiation emitter may be a time offset which is at most 100 ns.

In modern road traffic, an increasing discrepancy is emerging between “intelligent” vehicles equipped with a variety of communication tools, sensor technologies and assistance systems and “conventional” or technically less equipped road users like pedestrians and cyclists depending on their own human senses, i.e. substantially registering optical and acoustic signals by their eyes and ears, for orientation and associating risks of danger.

Further, pedestrians and cyclists are facing increasing difficulties in early recognition of warning signals by their own senses due to the ongoing development on the vehicle side Ike battery powered vehicles and autonomous driving. As a popular example, battery powered vehicles emit significant less noise as vehicles with combustion engines. Consequently, electric vehicles may be already too close before being detected by a pedestrian or cyclist to react proper.

On the other hand, conventional road users like pedestrians and cyclists also depend on being detected correctly by vehicles driving autonomously. Further, the software controlling the autonomous driving sequence and the vehicle has to provide an adequate procedure in response to the detection of other traffic participants, including conventional road users like pedestrians and cyclist as well as others, e.g. motorcyclists and third party vehicles. Possible scenarios may be e.g. adapting the speed of the vehicle or maintaining a distance when passing or decelerate to avoid a collision or initiating an avoidance maneuver or others. In the event of twilight or darkness, further requirements arise for autonomous vehicles. Another challenge are the individual characteristics of traffic participants not following distinct patterns making it exceedingly difficult to be taken into account and managed by mathematical algorithms and artificial intelligence methods.

Pedestrians and cyclists are currently used to traditional non-autonomously driving vehicles with combustion engines and are able to usually recognize an upcoming risk intuitively and without significant attentiveness, at least as long as they are not distracted. Such distraction is increasing due to the omnipresence of smartphones and their respective use causing optical and mental distraction or the use of acoustic media devices overlaying surrounding sounds. Further, the established ways of non-verbal communication between traffic participants by eye contact, mimic and gestures cannot be implemented in autonomous vehicles without enormous efforts, if at all.

Different approaches to enable the communication between autonomous vehicles and other traffic participants are under discussion, e.g. lightbars, displays on the exterior of the vehicle or vehicles projecting symbols onto the road.

However, there's still the problem of detecting the presence of other traffic participants, in particular pedestrians and cyclists, by an autonomous vehicle or a vehicle driving in an at least partially autonomous mode in a secure and reliable manner and to initiate an adequate subsequent procedure. Further, it is also a requirement to enable the other traffic participants, in particular pedestrians and cyclists, to notice autonomous vehicles or vehicles driving in an at least partially autonomous mode and/or electric vehicles driven by batteries at times.

Detailed Disclosure of the Disclosure “System to detect and/or communicate with a traffic participant”.

Accordingly, it is an object of the disclosure to propose a system and method to detect and/or communicate with a traffic participant which increases the safety in road traffic and improves the reliability of mutual perception.

The object is solved by a system to detect and/or to communicate with a traffic participant representing a first object according to Example 1x, a respective method according to Example 15x and a computer program product according to Example 16x. Further aspects of the disclosure are given in the dependent Examples.

The disclosure is based on a system to detect and/or communicate with a traffic participant representing first object, comprising a distance measurement unit intended to be allocated to the first object and configured to determine a distance to a second object representing a further traffic participant, based on a run-time of a signal pulse emitted by an first emission unit, reflected from the second object and detected by a detection unit of the distance measurement unit to enable the traffic participant to orient in road traffic. Allocated in the context of this disclosure means that any part of a distance measurement unit may be functionally connected with and/or physically attached to or entirely embedded into an object or parts of an object. According to the disclosure, the system further comprises an acquisition and information unit intended to be allocated to the second object and configured to detect the signal pulse emitted by the first emission unit and to output an information signal noticeable by human senses (e.g. touch, sight, hearing, smelling, tasting, temperature sensing, feeling of inaudible acoustic frequencies, balance, magnetic sensing and the like) depending on the detection result.

A traffic participant may be a person participating in road traffic or a corresponding vehicle used by such person. In regards to a vehicle as traffic participant, the inventive system can also be used without the vehicle being actively driven, e.g. to detect the vehicle as an obstacle. Thus, the inventive system may also provide bene-fits even if the traffic participants in general do not move.

The first and second object representing a traffic participant is may be an object that is mobile but still provides a representation of the traffic participant when used. A respective mobile object can be used by different traffic participants, e.g. a person owning different cars does not need to provide each car with such object, Examples for mobile objects are portable electronic devices, garments as explained later, accessories, like canes, or other articles associated with traffic participants. Alternatively, the object may be incorporated in a vehicle, e.g. an automobile, a motorbike, a bike, a wheel chair, a collator or the like. The incorporation of the object provides a continuous availability of the object when using the vehicle. In other words, the object is not prone of being forgotten or lost. Further, incorporating or at least connecting the first and/or second object with a vehicle used by a traffic participant may al-low to use the already existing power supply of the vehicle, like a battery or dynamo, to ensure operational readiness.

The distance measurement unit intended to be allocated to the first object and the acquisition and information unit intended to be allocated to the second object may be separate units to be affixed or connected otherwise to the respective object to provide a positional relationship. Alternatively, the units may be incorporated in the respective objects. Similar to the description of mobile or incorporated objects, separate or incorporated units each providing their own benefits.

In some embodiments, the distance measurement unit is a LIDAR Sensor Device and the first emission unit is a First LIDAR Sensing System comprising a MAR light source and is configured to emit electromagnetic signal pulses, in some implementations in an infrared wavelength range, in particular in a wavelength range of 850 nm up to 8100 nm, and the acquisition and information unit provides an optical detector adapted to detect the electromagnetic signal pulses, and/or the distance measurement unit is a ultrasonic system and the first emission unit is configured to emit acoustic signal pulses, in some embodiments in an ultrasonic range, and the acquisition and information unit provides an ultrasonic detector adapted to detect the acoustic signal pulses. In this context, the term ‘optical’ refers to the entire electromagnetic wavelength range, i.e. from the ultraviolet to the infrared to the micro-wave range and beyond. In some embodiments the optical detector may comprise a detection optic, a sensor element and a sensor controller.

The LIDAR Sensor Device allows to measure distances and/or velocities and/or trajectories. Awareness of a velocity of another traffic participant due to the velocity of the second object may support the initiation of an adequate subsequent procedure. In this regard, the distance measurement unit may be configured to consider the velocity of the second object, the velocity of itself and moving directions for risk assessment in terms of a potential collision. Alternatively, those considerations may be performed by a separate control unit of the first object or otherwise associated with the traffic participant based on the distance and velocity information provided by the distance measurement unit.

According to the disclosure, a LIDAR Sensor Device may include a distance measurement unit and may include a detector. A LIDAR Sensor System may include a LIDAR Sensor Management Software for use in a LIDAR Sensor Management System and may also include a LIDAR Data Processing System.

The LIDAR Sensor Device is in some embodiments adapted to provide measurements within a three dimensional detection space for a more reliable detection of traffic participants. With a two dimensional detection emitting signal pulses in a substantially horizontal orientation to each other, second objects may not be detected due to obstacles being in front of the second object in a propagation direction of the signal pulses. The advantages of a three-dimensional detection space are not restricted on the use of a LIDAR sensing device but also applies to other distance measurement technologies, independent of the signal emitted being optical or acoustic.

The emission of optical pulses in an infrared wavelength range by the first emission unit avoids the disturbance of road traffic by visible light signals not intended to pro-vide any information but used for measurement purposes only.

Similarly, the use of an ultrasonic system as distance measurement unit to emit acoustic signal pulses, in some implementations in an ultrasonic range, provides the advantage of using signal pulses usually not being heard by humans and as such not disturbing traffic participants. The selection of a specific ultrasonic range may also take the hearing abilities of animals into account. As a result, it's not only to protect pets in general but in particular “functional animals”, like guide dogs for blinds or police horses from being irritated in an already noisy environment.

An ultrasonic system is in some embodiments used for short ranges of a few meters. A system providing an ultrasonic system combined with a LIDAR sensing device is suitable to cover short and long ranges with sufficient precision.

The acquisition and information unit provides a detector adapted to detect the respective signal pulses, e.g. in the event of the use of an emission unit emitting optical signal pulses an optical detector or in the event of the use of an emission unit emitting acoustic signal pulses an acoustic detector. The detection of optical signal pulses in an infrared wavelength range may be implemented by one or more photo diodes as detector of the acquisition and information unit of the allocated to the second object.

To avoid the detection of signal pulses from other emitters than first objects to be detected, the detectors may be designed to receive only selected signals. Respective filters, like band filters, adapted to receive signals in a specified range may be used advantageously. As an example, an optical detector provides a band filter to only transmit wavelengths typically emitted by LIDAR sensing device, like 905 nm and/or 1050 nm and/or 1550 nm. The same principle applies to acoustic detectors.

The system may also provide a distance measurement unit configured to emit both, optical and acoustic, signal pulse types by one or a plurality of emission units. Emit-ting different types of signal pulses may provide redundancy if the detector of the acquisition and information unit is configured to detect both signal pulse types or the acquisition and information unit provides both respective detector types in the event of signal disturbances. Further, two signal types may allow the detection of the first object independent of the type of detector of the acquisition and information unit of the second object, here being an optical or acoustic detector.

In principle, the detector or detectors of the acquisition and information unit may be point detectors or area detectors, like a COD-array. Single detectors may form an array of detectors in a line or areal arrangement.

Advantageously, the acquisition and information unit provides a or the detector, respectively, to detect optical or acoustic signal pulses, wherein the detector provides an arrangement of a plurality of detector elements with acceptance angles each opening in different directions, wherein the acceptance angles overlap, to enable a 360°-all-round detection in a horizontal direction when allocated to the second object.

The acceptance angles provide an overlap region in a distance from the detector elements depending of the respective acceptance angles of the detector elements, the number of detector elements and their spacing. A minimum distance may be selected to reduce the number of detector elements. The minimum distance may be defined as a distance threshold which can be assumed as not providing a significant reduction in risk by a warning if the distance of the detected first object falls be-low the threshold. As an example, if the detector of the acquisition and information unit detects the first object in a distance less than 30 cm, any warning may already be too late. In a variant, the minimum distance may be selected depending on the actual velocity of the first and/or second object or a relative velocity between the objects. The minimum distance increases with an increase in velocity. As the number of detectors may not be reduced as they have to cover lower as well as higher velocities, at least not all of the detectors have to be operated positively affecting the power consumption.

A 360°-all-round detection does not only allow an earlier warning but also provides more flexibility in positioning the acquisition and information unit or the second object.

According to an embodiment of the disclosure, the information signal noticeable by human senses outputted by the acquisition and information unit is a light optical signal with light in a wavelength range of 380 nm to 780 nm and/or an acoustic signal with tones in a frequency range of 16 Hz to 20.000 Hz and/or a mechanical vibration signal with vibrations in a frequency range of 1 Hz to 500 Hz. The acoustic frequency range may be selectable according to the age or the hearing abilities of a person or animal.

The information signal is advantageously selected such that it differs from other signals that may be noticeable in a traffic participant's environment. As an example, an acoustic signal of the acquisition and information unit should differ from a signal provided by a telephone device for incoming calls. Further, light optical signals may be selected such that users suffering from red-green colorblindness are not con-fronted with problems resulting from their deficiency. A mechanical vibration signal may provide an information signal noticeable independently from surrounding noise and light conditions. However, physical contact or at least a transmission path has to be established. Further, if a vibration signal may be difficult to be interpreted by a traffic participant, if more than one information, in particular quantitative information, shall be provided. As one predetermined setting may not fit for every individual traffic participant or every second object, the acquisition and information unit may provide a selection option to allow selection of at least one signal type and/or of at least one signal parameter within a signal type range. Independent of the individual traffic participant or the second object, light optical signals cannot only be used to inform the traffic participant represented by the second object but also supports the traffic participant and information recognition by others if the light optical signals are respectively designed.

The signal generating device may not be restricted to the output of one type of in-formation signal but may also be capable of providing different types of information signals in parallel and/or in series. As an example, smart glasses may display a passing direction and passing side of a first object by light optical signals, while the side piece or glass frame on the passing side emits a mechanical vibration and/or acoustic signal in parallel. When the first object changes its relative position to the second object, the visible or audible signals may change their position on their respective device, e.g. the display of a smartphone or the frame of a smart glass.

The information signal noticeable by human senses outputted by the acquisition and information unit may be continuous or pulsed. Light optical signals may be white or colored light or a series of different colors, e.g. changing with increasing risk from green to red. In some embodiments, light optical signals are emitted in a line of sight of the traffic participant represented by the second object to ensure perception by the traffic participant. Further, light optical signals may also be emitted in lateral or rearward directions to be recognized by other traffic participants to receive an information related to the detection of a first object and/or that the traffic participant represented by the second object may react in short term, e.g. initiating a sudden braking. The same principles may apply for acoustic signals.

In some embodiments, the acquisition and information unit comprises a or the detector, respectively, to detect optical or acoustic signal pulses and a control device and a signal generating device connected to each other and the detector, wherein the control device is configured to interpret the signal detected by the detector and to control the signal generating device such that the outputted information signal is outputted in a quality, in particular frequency or wavelength, respectively, and/or pulse duration and their change over time, noticeable by human senses depending on the detection result.

A detection result may be a velocity in general and/or a velocity of a distance reduction and/or a distance and/or a direction of a detected traffic participant represented by a first object. The frequency may, for example, be increased with a decreasing distance. The term frequency in this context is directed to a change in tone or color and; or the repetition rate of the information signal. In general, the quality of the out-putted information signal may represent the risk of a present situation in road traffic by increasing perception parameters to be noticed with increasing risk.

In an embodiment the signal generating device, in the event of outputting a light optical signal with light in a wavelength range of 380 nm to 780 nm, provides a number of light sources, in some implementations LEDs, mini-LEDs or micro-LEDs, arranged to display a two or three-dimensional information.

LEDs are easy to implement and usually provide a long lifetime and therefore reliability, in particular important for safety applications.

As a variant or additionally, the signal generating device, in the event of outputting a light optical signal with light in a wavelength range of 380 nm to 780 nm, comprises a rigid or flexible flat screen display device and/or a smartphone, a smart watch, a motor cycle helmet, a visor or an augmented reality device.

A display device may not only provide a light optical signal as such but may also provide a light optical signal in form of a predetermined is display element, like an arrow indication an approaching direction of a first object, or an icon, like an exclamation mark, both representing a particular road traffic situation or associated risk. Further, the display element may show further information, e.g. the quantitative value of a distance and/or a velocity.

As a further variant or additionally, the signal generating device, in the event of outputting a light optical signal with light in a wavelength range of 380 nm to 780 nm, comprises one or more light sources each providing one or more optical waveguides coupled to the respective light source and capable of emitting light over the length of the optical waveguide, and/or the signal generating device, in the event of output-ting a light optical signal with light in a wavelength range of 380 nm to 780 nm, comprises one or more self-luminous fibers.

Optical waveguides allow flexible guidance of a light optical signal to a target location by total reflection. Optical waveguides may also be designed to output light over their length or defined areas. Self-luminous fibers or yarn may emit light passively or actively. Accordingly, light optical signals may be distributed over larger and/or multiple areas to be better noticed.

Depending on the design, waveguides and/or self-luminous fibers may be arranged to provide light optical signals of a predetermined shape and/or different colors or shades.

Alternatively or in addition the use of waveguides or self-luminous fibers, light optical signals may be coupled into planar areal segments to be outputted at least one output surface after being scattered and homogenized within the segment.

In a further aspect of the disclosure, the system comprises a garment, in some implementations a textile garment, intended to be allocated to the second object, to provide the second object with the acquisition and information unit.

Examples of a garment are jackets, vests, in particular safety vests, trousers, belts, helmets, back bags or satchels. The acquisition and information unit may be incorporated or affixed to the garment or may be disposed in a pocket or similar receiving part of such garment. In the event of using waveguides or self-luminous fibers, the waveguides or fibers may be woven in textile garments or textile parts of a garments. Alternatively, the waveguides or fibers form the textile garments or parts thereof respectively.

As textile garments are usually subject to be washed, the acquisition and information unit and it components waterproof or provided with a waterproof enclosure. Alternatively, the acquisition and information unit or at least sensitive parts thereof are detachable, e.g. to exclude them from any washing procedures.

According to a further aspect of this aspect, the system comprises a device for current and voltage supply connected to the acquisition and information unit, and in some embodiments a power source to be coupled thereto, in particular a battery or a rechargeable accumulator.

The connection provides easy exchange of current and power supplies, like batteries, power banks and other portable power sources, or removal. Further, an interface to connect a current and power supply may provide access to current and power supplies of other systems and reduces the number of power sources accordingly.

In some embodiments, the first emission unit of the distance measurement unit of the first object to be detected is configured to transmit an information of a position, a distance, a velocity and/or an acceleration of the first object to be detected by the signal pulses or a series of signal pulses, respectively, by frequency modulation or pulse modulation or a pulse code, wherein the control device of the acquisition and information unit interprets the additional information provided by the signal puls(es) detected by the detector and compares the additional information with the position, velocity and/or acceleration of the belonging second object, and outputs the information signal depending on said comparison.

This kind of comparison does not only consider the position and moving characteristics of the traffic participant representing first object but also their relation to the second object. The position and moving characteristics of the first object in terms of frequency modulation may provide, for example, a distance value according to the frequency of the signal pulses. A pulse modulation may provide the same information by way of using different signal pulses or signal pulse amplitudes. A pulse code may provide such information similar to the use of Morse signals.

According to a further aspect of this aspect, the acquisition and information unit provides a second emission unit configured to transmit a signal pulse or a series of signal pulses to a detector of the first object to be detected via an optical or acoustic transmission path, in some embodiments the same transmission path used by the detector of the acquisition and information unit to receive the signal pulse or the signal pulses of the first emission unit of the first object to be detected, wherein the control device is configured to determine a position, a distance, a velocity and/or an acceleration of its own and to transmit this information to the detector of the first object to be detected by frequency modulation or pulse modulation or a pulse code of the signal pulse or signal pulses.

The bilateral communication between the first and second object allows the first object to receive the same or similar information about the second object as already described in the context of the second object detecting the first object. As various examples of providing noticeable information are described, the Term “similar” relates to at least one of the examples, while the second object may use other ways of providing information.

The information itself as well as the type of outputting such information is “similar” in term of a detection information but may vary in its specific implementation. As an example, a second object representing a pedestrian may receive a distance signal of a first object outputted as light optical signal while a first object representing a driver of an automobile receives an acoustic signal of a distance and moving direction of the second object.

Alternatively or in addition, the second emission unit emits a signal comprising in-formation about the traffic participant represented by the second object, Such information may be the type of traffic participant, like being a pedestrian or cyclist, his/her age, like below or above a certain threshold, disabilities important to be considered in road traffic, and/or a unique identity to allocate information signals emitted from the second emission unit to the identity.

The detector of the first object to detect the signal puls(es) emitted from the second emission unit may be a detector of the detection unit of the distance measurement unit or a separate detector.

In some embodiments, the acquisition and information unit comprises a storage unit and an input unit, wherein thresholds for positions, distances, velocities, accelerations and/or combinations thereof can be set in the storage unit via the input unit, wherein no or restricted information from the second emission unit is transmitted to the first object to be detected in the event that a corresponding value provided by the detected signal pulse or series of signal pulses exceeds or falls below a set thresh-old or combinations thereof.

The setting of thresholds prevents the output of information by the second emission unit of the acquisition and information unit for every detected signal pulse. In particular in an environment with lots of traffic participants, the number of transmitted in-formation by second emission units to the first object may otherwise create undistinguishable information sequences reducing the ability to identify most important warnings. This would rather be irritating than supporting orientation and increasing safety in road traffic. Further, it can be assumed that a user gets used to a more or less constantly blinking or beeping device without paying attention anymore, if not even turning off such device or a respective functionality. Accordingly, the output of information may be limited to the ones required or desired by the use of thresholds.

Thresholds may not only be quantitative values but may also comprise qualitative properties, like only transmitting information if a second object is moving. The thresholds may also consider reciprocal relationships, e.g. if a second object is moving in a direction x with a velocity y, a position signal is transmitted to the first object, when the measured distance falls below z. As another example considering basic principles, an information is not transmitted by the second emission unit if a velocity of the first object is below a certain threshold. However, the second emission unit may still transmit other information signals not depending on thresholds. Further, the detected information signals may also be prioritized. Accordingly, the second emission unit may only emit one information representing highest risk based on a defined ranking or underlying algorithm.

The same principles of setting thresholds may apply to the signal generating device of the acquisition and information unit with respect to the output of an information signal noticeable by human senses depending on the detection result. In particular, the control device of the acquisition and information unit may control thresholds and/or prioritization of signal pulses detected from a plurality of first objects. The control device controls the signal generating device such that, for example, only a first object with the closest distance and/or a first object with the highest velocity and/or first objects with a moving direction potentially crossing path of the second object cause the generation of an information signal. To interpret a detected signal pulse in terms of a potential crossing of moving paths, the signal pulse may be accompanied by a path information, e.g. based on an activated turn signal or a routing by a navigation system.

In a further aspect, the acquisition and information unit comprises a radio communication unit. The radio communication unit may be part of the second emission unit or separate and transmits information signals as electrical signal or radio signal, in particular a Bluetooth signal, to a further signal generating device. The further signal generating device may be allocated to the traffic participant represented by the second object or to other traffic participants. With respect to the traffic participant represented by the second object, the second object may be placed in a position for better detection of the signal pulses emitted by the first emission unit while having inferior capabilities to provide a traffic participant with respective information signals. Further, other traffic participants not equipped with an acquisition and information unit may receive information about the traffic situation and potential risks nearby. The further signal generating device may be a smart device, like smart phones, smart watches or augmented reality devices, e.g. smart glasses or a head mounted display.

The disclosure is also directed to a method to detect and/or communicate with a traffic participant representing first object, comprising:

Emitting a signal pulse intended to determine a distance by a first emission unit of a distance measurement unit allocated to a the first object, reflecting the signal pulse at a second object representing a further traffic participant, detecting the reflected signal by a detection unit of the distance measurement unit and determination of the distance based on the measured run-time, further detecting the signal pulse emitted by the first emission unit by an acquisition and information unit allocated to the second object, and outputting an information signal noticeable by human senses by the acquisition and information unit depending on the detection result.

The method provides the same advantages as already described for the disclosed system and respective aspects.

In another aspect, the method may include further steps with respect to the described system embodiments. As an example, the method may include emitting a signal pulse or a series of signal pulses to a detector of the first object or another object representing another traffic participant or traffic control system via an optical or acoustic transmission path, in some implementations the same transmission path used by the acquisition and information unit to receive the signal pulse or signal pulses of the first emission unit. Alternatively or in addition, radio signal pulses may be transmit-led. In some implementations the signal pulse or signal pulses may be encrypted.

The signal pulse or signal pulses may transmit information signals, like a position, a distance, a velocity and/or an acceleration of the second object or acquisition and information unit, respectively, or the control device representing the acquisition and information unit and therefore the second object.

Further information may comprise but is not limited to personal information about the traffic participant represented by the second object, e.g. his or her age, disabilities or other indicators that may influence the individual performance in road traffic. In some implementations particularly personal information may be subject to encryption.

The disclosure is also directed to a computer program product embodied in a non-transitory computer readable medium comprising a plurality of instructions to exe-cute the method as described and/or to be implemented in the disclosed system.

The medium may be comprised by a component of the system or a superior provider, e.g. a cloud service. The computer program product or parts thereof may be subject to be downloaded on a smart device as an app. The computer program product or parts thereof may allow and/or facilitate access to the internet and cloud-based services.

Further advantages, aspects and details of the disclosure are subject to the claims (Example 1x, 2x, 3x . . . ), the following description of preferred embodiments applying the principles of the disclosure and drawings. In the figures, identical reference signs denote identical features and functions.

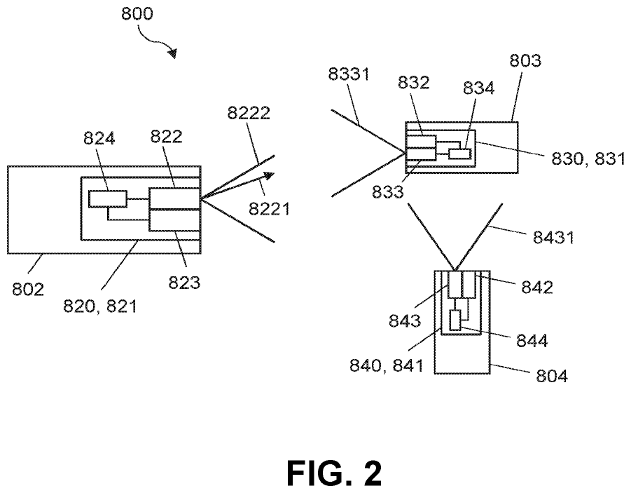

FIG. 2 shows an explanatory road traffic situation with an autonomously driven electric car as traffic participant 802 represented by a first object 820, a pedestrian as traffic participant 803 represented by a second object 830 and a cyclist as traffic participant 804 represented by a further second object 840. The system 800 to detect traffic participant 802 represented by a first object 820 comprises a first object 820 incorporated in the car, in some embodiments as part of a general monitoring system, to represent the car as traffic participant 802 by the first object 820. The first object 820 provides a distance measurement unit 821 to determine a distance to a second object 830, 840 representing further traffic participants 803, 804 as described later. Here, the distance measurement unit 821 is a LIDAR sensing device measuring a distance based on a run time of a signal pulse 8221 emitted by a first emission unit 822, here a LIDAR light source, reflected from a second object 803, 804 and detected by a detection unit 823 of the distance measurement unit 821, Even though only one signal pulse 8221 is shown, the LIDAR sensing device provides a plurality of signal pulses 8221 within an emitting space 8222 based on the technical configuration of the LIDAR sensing device and/or respective settings. Traffic participants 802, 803, 804 may be mobile or immobile, ground based or aerial.

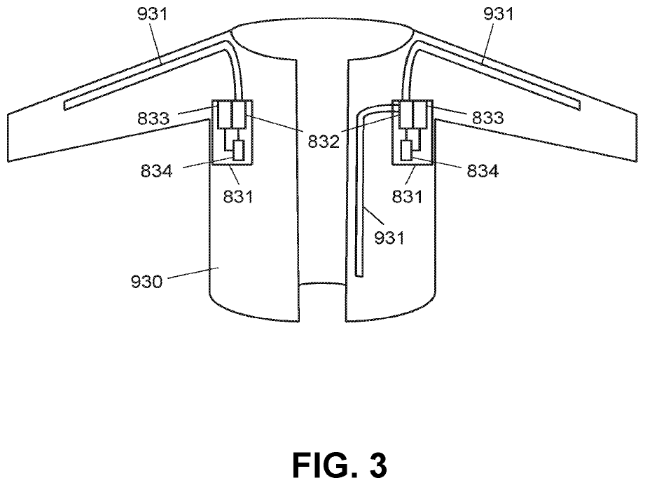

Further, the pedestrian as traffic participant 803 and the cyclist as traffic participant 804 are each represented by a second object 830 and 840, respectively. As an ex-ample, the second object 830 representing the pedestrian as traffic participant 803 is a garment 930 as described later with reference to FIG. 3 and the second object 840 representing the cyclist as traffic participant 804 is affixed to the handlebar of the bike. Each of the second objects 830, 840 comprises an acquisition and information unit 831, 841. The respective acquisition and information unit 831, 841 may be incorporated in the second object 830, 840 or otherwise affixed or connected to the second object to be allocated to the second object 830, 840. The acquisition and information unit 831, 841 is configured to detect a signal pulse 8221 emitted by the first emission unit 822, here by a detector 833, 843, Instead of a single detector, multiple detectors may be provided to enhance the detection space. The detection of the signal pulse 8221 by one detector 833, 843 is given as an example to describe the basic principle. The detectors 833, 843 each providing an acceptance angle 8331, 8431 for the detection of the signal pulse 8221, depending of the technical configuration or an individual setting option. If a signal pulse 8221 is detected by a detector 8331, 8431, an information signal noticeable by human senses depending on the detection result is outputted. In the explanatory embodiment shown in FIG. 2, the acquisition and information units 831, 841 each providing a control device 834, 844 controlling a signal generating device 832, 842 depending on different threshold settings.

As an example for different threshold settings, the control device 833 of the acquisition and information unit 831 causes the signal generating device 832 to output an information signal only, it the detected signal pulse 8221 indicates a distance less than 10 m. As a pedestrian as traffic participant 803 represented by the second object 830 is relatively slow, such distance should be sufficient to provide the pedestrian with enough time to react, Other settings can be selected, e.g. if the pedestrian goes tor a jog anticipated with higher moving velocities. To allow an automatic setting of thresholds, the control device 834 may be configured to adapt thresholds depending on sensed motion characteristics of the pedestrian or the first object. On the other hand, a cyclist as traffic participant 804 usually moves with much fast speed, so the control device 844 causes the signal generating device 842 to output an in-formation signal already, if the detected signal pulse 8221 indicates a distance less than 20 m. The control device 844 may also be configured to provide different and/or automatic settings as described for the control device 834.

The acquisition and information units 831, 841 each providing detectors 833, 843 configured to detect infrared optical signal pulses by one or multiple photodiodes.

Here, each detector 833, 843 comprises multiple photodiodes arranged horizontally with overlapping acceptance angles around each of the acquisition and information unit 831, 841 to provide a detection space or the signal puls(es) emitted by the LI-DAR sensing device approaching a 360°-all-round detection to the extent possible.

The detectors 833, 843 each comprising band filters to reduce the detection to the main LIDAR wavelength(s) to exclude noise signals. Here, the band filter only transmits wavelength substantially equal to 1050 nm. The term “substantially” takes usual technical tolerances with respect to the emitted signal and the band filter into account. Further, the wavelength(s) to be transmitted may be selected as individual settings or according to a measurement of a signal strength.

The signal generating devices 832, 842 output different information signals. The signal generating device 832 outputs a light optical signal and the signal generating device 842 outputs an acoustic signal. However, the signal generating devices 832, 842 may also be configured to output another information signal or multiple types of information signals which may depend on a defection result, on an individual selection by the respective traffic participant or automatically set depending on surrounding conditions, e.g. light optical signals if noise exceeding a particular threshold is sensed or acoustic signals if a sensed surrounding illumination may impede easy recognition of light optical signals.

Further, the acquisition and information units 831, 841 each comprising a second emission unit (not shown) to transmit a signal pulse or a series of signal pulses to the detection unit 823 of the distance measurement unit 821 or another defector of the first object 820. The signal pulses may comprise object identification codes, for example object type and classification, object velocity and trajectory, and the method of movement. The signal puls(es)) provide(s) the control device 824 with information in addition to the measured distance, in particular with regards to a position in term of the orientation of the second object 830, 840 with respect to the first object 820, a distance for verification purposes, a velocity of the second object 830, 840 and/or an acceleration of the second object 830, 840. The respective information is provided by the control device 834, 844 of the second object 830, 840.

In the embodiment shown in FIG. 2, the second emission unit of the acquisition and information unit 831 comprises a radio communication unit to transmit the in-formation signals as electrical signal to a further signal generating device. The signals may be transmitted directly or via a further control device to process the received signals before controlling the signal generating device accordingly. Here, a Bluetooth protocol is used to provide a smart phone of the pedestrian 803 with respective information. Further, the Bluetooth signals may be received by other traffic participants. Accordingly, a communication network is established to extend the detection space virtually or to provide traffic participants that are either equipped or not equipped with a system 800 to detect a traffic participant 802 representing first object 820 with respective information. Parts of the communication network may work, at least during certain time periods. In a unilateral mode, other parts of the communication network may work in bilateral or multilateral modes. Access rights, information signals and other setting may be administered by an app, IoT or cloud services and may be displayed graphically, i.e. in pictures, symbols or words, on a suited device, for example a smartphone, a smartwatch or a smart glass (spectacles).

With respect to interaction of traffic participants and the output of information signals, a further explanatory application is the control of the signal generating devices by the respective control devices of the acquisition and information units based on the electrical signals transmitted by the radio communication units. As an example, several pedestrians walk at a distance of 50 m behind each other. A LIDAR sensing device as distance measurement unit would detect all of the pedestrians and the acquisition and Information units of the detected pedestrians would output an in-formation signal, if no further measure is taken. The plurality of information signals would be rather confusion as they don't provide any further indication of the detected traffic participant represented by a first object as the information signal appear over a long distance range. To provide better guidance, the first emission unit may be configured to transmit a distance information to the acquisition and information units, so that the signal generating devices may be controlled according to set distance thresholds and/or a moving direction. Alternatively or in addition, the radio communication units may be used to transmit information about the traffic participant represented by the first object. The control devices of the acquisition and information units may judge whether the received information is prioritized according to an underlying algorithm and if so, the control device does not cause the signal generating device to output an information signal. The underlying algorithm may prioritize distance signals, such that only the acquisition and information unit allocated to the traffic participant closest to the first object outputs are Information signal. In a further variant still, all or at least a plurality of the acquisition and information units output an information signal. However, the information signals provide a different quality. In the event of light optical signals, the signals generated by the signal generating device closest to the first object appear brighter than the ones in a farer distance, Such visual “approaching effect” may also be achieved by the setting of distance-depending thresholds for the quality of the quality of the outputted information signals. As an example, if an electrically operated car comes dose to a detected pedestrian, it may switch on or increase audible noise. In another aspect, an approaching battery powered vehicle may switch on a sound generating device and/or vary or modulate an acoustical frequency.

FIG. 3 shows a garment 930, here a jacket as explanatory embodiment, that may be worn by a pedestrian or cyclist. The garment 930 provides two acquisition and information units 831 each comprising a detector 833, a signal generating device 832 and a control device 834. The acquisition and information units 831 are incorporated in the garment 930 but may be at least partially removable, in particular with regards to the power supply and/or smart devices, e.g. smart phones or the like, for washing procedures.

In this embodiment, the signal generating unit 832 is a light module for generating light optical signals to be coupled into waveguides 931. The waveguides successively output the light optical signals over their length. In principle, the light module comprises one or more LEDs, in particular LEDs providing different colors. Each LED couples light in one or more waveguides 931 separately. Alternatively, one or more waveguides 931 may guide the light of several LEDs.

To protect the waveguides 931 and the light module against moisture and to ease the assembly to the garment 930, the waveguides 931 and the light module may be molded together. Alternatively or in addition, other components, like the detector 833 and/or the control device 834, may also form part of an or the molded configuration, respectively.

The waveguide 931 is in some implementations made of a thermoplastic and flexible material, e.g. polymethylmethacrylate (PMMA) or to thermoplastic polyurethan (TRU).

The garment 930 may provide further acquisition and information units 831 in lateral areas, like shoulder sections or sleeves, or on the back.

The acquisition and information units 831 are provided with a is power supply (not shown), like a battery, accumulator and/or an interface to be coupled to a power bank or smart phone. The power supply may be coupled to the acquisition and in-formation unit 831 or incorporated in the acquisition and information unit 831. Further, each acquisition and information unit 831 may provide its own power supply or at least some of the acquisition and information units 831 are coupled to one power supply.

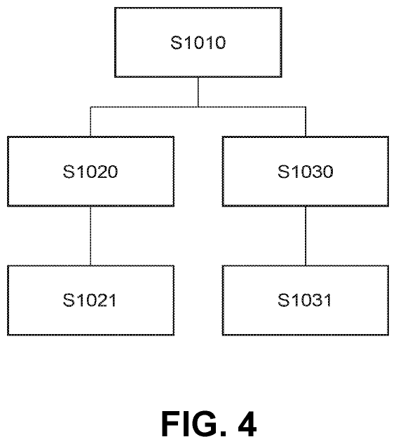

The basic principle of the inventive method to detect a traffic participant 802 representing a first object 820 is shown in FIG. 4. In step S1010 a signal pulse 8221 in-tended to determine a distance by a first emission unit 822 of a distance measurement unit 821 allocated to the first object 820 is emitted. The emitted signal pulse 8221 is then reflected at a second object 830, 840 representing a further traffic participant 803, 804 in accordance with step S1020. The reflected signal is detected by a detection unit 823 of the distance measurement unit 821 and a distance is determined based on the measured run-time in step S1021.

Further, the signal pulse 8221 emitted by the first emission unit 822 is detected by an acquisition and information unit 831, 841 allocated to the second object 830, 840 in accordance with step S1030. In step 31031, an information signal noticeable by human senses is outputted by the acquisition and information unit 831, 841 de-pending on the detection result.

Even though FIG. 4 shows the steps S1020 and S1021 in parallel to steps S1030 and S1031, the method may also be applied in series, e.g. if the acquisition and information unit 831, 841 should also be provided with a distance information by the first emission unit 822. Further, the acquisition and information unit 831 841 may also emit a signal pulse or a series of signal pulses to a detector of the first object or another object representing another traffic participant or traffic control system via an optical or is acoustic transmission path, in some implementations the same transmission path used by the acquisition and information unit to receive the signal pulse or signal pulses of the first emission unit. Alternatively or in addition, radio signal pulses may be transmitted.

It is to be noted that the given examples are specific embodiments and not intended to restrict the scope of protection given in the claims (Example 1x, 2x, 3x . . . ). In particular, single features of one embodiment may be combined with another embodiment. As an example, the garment does not have to provide a light module as signal generating device but may be equipped with an acoustic signal generating device. Further, instead of waveguides, self-luminous fibers may be used. The disclosure is also not limited to specific kinds of traffic participants. In particular, the traffic participant represented by the first object does not have to be a driver of a motor vehicle or the traffic participants represented by the second object are not necessarily non-motorized. The traffic participants may also be of the same type.

Various embodiments as described with reference to FIG. 2 to FIG. 4 above may be combined with a smart (in other words intelligent) street lighting. The control of the street lighting thus may take into account the information received by the traffic participants.

In the following, various aspects of this disclosure will be illustrated:

Example 1x is a system to detect and/or communicate with a traffic participant representing a first object. The advantageous system comprising: a distance measurement unit intended to be allocated to the first object and configured to determine a distance to a second object representing a further traffic participant based on a run-time of a signal pulse emitted by a first emission unit, reflected from the second object and detected by a detection unit of the distance measurement unit to enable the traffic participant to orient in road traffic, an acquisition and information unit intended to be allocated to the second object and configured to detect the signal pulse emitted by the first emission unit and to output an information signal noticeable by human senses depending on the detection result.

In Example 2x, the subject matter of Example 1x can optionally include that the distance measurement unit is a LIDAR Sensor Device and the first emission unit is a First LIDAR Sensing System comprising a

LIDAR light source and is configured to emit optical signal pulses, for example in an infrared wavelength range, in particular in a wavelength range of 850 nm up to 8100 nm, and the acquisition and information unit provides an optical detector adapted to detect the optical signal pulses, and/or the distance measurement unit is an ultrasonic system and the first emission unit is con-figured to emit acoustic signal pulses, for example in an ultrasonic range, and the acquisition and information unit provides an ultrasonic detector adapted to detect the acoustic signal pulses.

In Example 3x, the subject matter of any one of Example 1x or 2x can optionally include that the acquisition and information unit provides a or the detector, respectively, to detect optical or acoustic signal pulses, wherein the detector provides an arrangement of a plurality of detector elements with acceptance angles each opening in different directions, wherein the acceptance angles overlap, to enable a 300°-all-round detection in a horizontal direction when allocated to the second object.

In Example 4x, the subject matter of any one of Example 1x to 3x can optionally include that the information signal noticeable by human senses outputted by the acquisition and in-formation unit is a light optical signal with light in a wavelength range of 380 nm to 780 nm and/or an acoustic signal with tones in a frequency range of 16 Hz to 20.000 Hz and/or a mechanical vibration signal with vibrations in a frequency range of 1 Hz to 500 Hz.

In Example 5x, the subject matter of any one of Example 1x to 4x can optionally include that the acquisition and information unit comprises a or the detector, respectively, to detect optical or acoustic signal pulses and a control device and a signal generating device connected to each other and the detector, wherein the control device is configured to interpret the signal detected by the detector and to control the signal generating device such that the outputted in-formation signal is outputted in a quality, in particular frequency or wavelength, respectively, and/or pulse duration and their change over time, noticeable by human senses depending on the detection result.

In Example 6x, the subject matter of Example 5x can optionally include that the signal generating device, in the event of outputting a light optical signal with light in a wavelength range of 380 nm to 780 nm, provides a number of light sources, for example LEDs, mini-LEDs or micro-LEDs, arranged to display a two or three-dimensional information.

In Example 7x, the subject matter of Example 5x can optionally include that the signal generating device, in the event of outputting a light optical signal with light in a wavelength range of 380 nm to 780 nm, comprises a rigid or flexible flat screen display device and/or a smartphone, a smart watch or an augmented reality device.

In Example 8x, the subject matter of Example 5x can optionally include that the signal generating device, in the event of outputting a light optical signal with light in a wavelength range of 380 nm to 780 nm, comprises one or more light sources each providing one or more optical waveguides (300.1) coupled to the respective light source and capable of emitting light over the length of the optical waveguide (300.1), and/or the signal generating device, in the event of outputting a light optical signal with light in a wavelength range of 380 nm to 780 nm, comprises one or more self-luminous fibers.

In Example 9x, the subject matter of any one of Example 5x to 8x can optionally include that the system further includes a garment, for example a textile garment, intended to be allocated to the second object, to provide the second object with the acquisition and information unit.

In Example 10x, the subject matter of Example Ox can optionally include that the system further includes a device for current and voltage supply connected to the acquisition and information unit, and for example a power source to be coupled thereto, in particular a battery or a rechargeable accumulator.

In Example 11x, the subject matter of any one of Example 5x to 10x can optionally include that the first emission unit of the distance measurement unit of the first object to be detected is configured to transmit an information of a position, a distance, a velocity and/or an acceleration of the first object to be detected by the signal pulses or a series of signal pulses, respectively, by frequency modulation or pulse modulation or a pulse code, wherein the control device of the acquisition and information unit interprets the additional information provided by the signal puls(es) detected by the detector and compares the additional information with the position, velocity and/or acceleration of the belonging second object, and outputs the information signal depending on said comparison.

In Example 12x, the subject matter of any one of Example 5x to 11x can optionally include that the acquisition and information unit provides a second emission unit configured to transmit a signal pulse or a series of signal pulses to a detector of the first object to be detected via an optical or acoustic transmission path, in some implementations the same transmission path used by the detector of the acquisition and information unit to receive the signal pulse or the signal pulses of the first emission unit of the first object to be detected, wherein the control device is configured to determine a position, a distance, a velocity and/or an acceleration of its own and to transmit this information to the detector of the first object to be detected by frequency modulation or pulse modulation or a pulse code of the signal pulse or signal pulses.

In Example 13x, the subject matter of Example 12x can optionally include that the acquisition and information unit comprises a storage unit and an input unit, wherein thresholds for positions, distances, velocities, accelerations and/or combinations thereof can be set in the storage unit via the input unit, wherein no or restricted information from the second emission unit is transmitted to the first object to be detected in the event that a corresponding value provided by the detected signal pulse or series of signal pulses exceeds or falls below a set threshold or combinations thereof.

In Example 14x, the subject matter of any one of Example 1x to 13x can optionally include that the acquisition and information unit comprises a radio communication unit.

Example 15x is a method to detect and/or communicate with a traffic participant representing a first object. The method includes: Emitting a signal pulse intended to determine a distance by a first emission unit of a distance measurement unit allocated to the first object, reflecting the signal pulse at a second object representing a further traffic participant, detecting the reflected signal by a detection unit of the distance measurement unit and determination of the distance based on the measured run-time, further detecting the signal pulse emitted by the first emission unit by an acquisition and information unit allocated to the second object, outputting an information signal noticeable by human senses by the acquisition and in-formation unit depending on the detection result.

Example 16x is a computer program product. The computer program product includes a plurality of instructions that may be embodied in a non-transitory computer readable medium to execute the method according to Example 15x and/or to be implemented in a system according to any of the Examples 1x to 14x.

### CONCLUSION

While various embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings is/are used. Those skilled in the art will recognize, or be able to ascertain using no more than routine experimentation, many equivalents to the specific advantageous embodiments described herein. It is, therefore, to be understood that the foregoing embodiments are presented by way of example only and that, within the scope of the appended claims and equivalents thereto, embodiments may be practiced otherwise than as specifically described and claimed. Embodiments of the present disclosure are directed to each individual feature, system, article, material, kit, and; or method described herein. In addition, any combination of two or more such features, systems, articles, materials, kits, and/or methods, if such features, systems, articles, materials, kits, and/or methods are not mutually inconsistent, is included within the scope of the present disclosure.

The above-described embodiments can be implemented in any of numerous ways. The embodiments may be combined in any order and any combination with other embodiments. For example, the embodiments may be implemented using hardware, software or a combination thereof. When implemented in software, the software code can be executed on any suitable processor or collection of processors, whether provided in a single computer or distributed among multiple computers.

Further, it should be appreciated that a computer may be embodied in any of a number of forms, such as a rack-mounted computer, a desktop computer, a laptop computer, or a tablet computer. Additionally, a computer may be embedded in a device (e.g. LIDAR Sensor Device) not generally regarded as a computer but with suitable processing capabilities, including a Personal Digital Assistant (PDA), a smart phone or any other suitable portable or fixed electronic device.

Also, a computer may have one or more input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computer may receive input information through speech recognition or in other audible format.

Such computers may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks, wired networks or fiber optic networks.

The various methods or processes outlined herein may be coded as software that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine.

In this respect, various disclosed concepts may be embodied as a computer readable storage medium (or multiple computer readable storage media) (e.g., a computer memory, one or more floppy discs, compact discs, optical discs, magnetic tapes, flash memories, circuit configurations in Field Programmable Gate Arrays or other semiconductor devices, or other non-transitory medium or tangible computer storage medium) encoded with one or more programs that, when executed on one or more computers or other processors, perform methods that implement the various embodiments of the disclosure discussed above. The computer readable medium or media can be transportable, such that the program or programs stored thereon can be loaded onto one or more different computers or other processors to implement various aspects of the present disclosure as discussed above.

The terms “program” or “software” are used herein in a generic sense to refer to any type of computer code or set of computer-executable instructions that can be employed to program a computer or other processor to implement various aspects of embodiments as discussed above. Additionally, it should be appreciated that according to one aspect, one or more computer programs that when executed perform methods of the present disclosure need not reside on a single computer or processor, but may be distributed in a modular fashion amongst a number of different computers or processors to implement various aspects of the present disclosure.

Computer-executable instructions may be in many forms, such as program modules, executed by one or more computers or other devices. Generally, program modules include routines; programs; objects; components, data structures, etc. that perform particular tasks or implement particular abstract data types. Typically the functionality of the program modules may be combined or distributed as desired in various embodiments.

Also, data structures may be stored in computer-readable media in any suitable form. For simplicity of illustration; data structures may be shown to have fields that are related through location in the data structure.

Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

Also, various advantageous concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an.” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined, Other elements may optionally be present other than the elements specifically identified by the “and/or” clause, whether related or unrelated to those elements specifically identified. Thus; as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one.” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the disclosure above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the eighth edition as revised in July 2010 of the United States Patent Office Manual of Patent Examining Procedures, Section 2111,03

For the purpose of this disclosure and the claims that follow, the term “connect” has been used to describe how various elements interface or “couple”. Such described interfacing or coupling of elements may be either direct or indirect. Although the subject matter has been described in language specific to structural features and/or methodological acts, it is to be understood that the subject matter defined in the appended claims is not necessarily limited to the specific features or acts described. Rather, the specific features and acts are disclosed as preferred forms of implementing the claims.

In the context of this description, the terms “connected” and “coupled” are used to describe both a direct and an indirect connection and a direct or indirect coupling.

1. A light detection and ranging (LIDAR) system comprising:
a distance measuring unit configured to emit a plurality of first pulses towards an object located in a field of view (FOV), wherein the object is associated with one or more markers; and
a detector configured to receive at least one second pulse from the one or more markers of the object, wherein each of the at least one second pulse indicates object information identifying the object.

2. The LIDAR system of claim 1, wherein each of the at least one second pulse is configured with a particular wavelength which represents an object class of the object.

3. The LIDAR system of claim 1, wherein the object information is modulated on the at least one second pulse.

4. The LIDAR system of claim 3, wherein the object information is modulated on the at least one second pulse via an amplitude modulation.

5. The LIDAR system of claim 1, wherein an intensity distribution of the plurality of first pulses has at least one subset that overlaps with an intensity distribution of the at least one second pulse.

6. The LIDAR system of claim 1, wherein the object information is wavelength-coded on the at least one second pulse.

7. The LIDAR system of claim 1, further comprising at least one filter configured to receive the at least one second pulse from the one or more markers and pass though some of the at least one second pulse at a given wavelength.

8. The LIDAR system of claim 1, wherein the object information includes at least one of position information, movement trajectories and object class.

9. The LIDAR system of claim 1, wherein each of the at least one second pulse includes amplified echo pulse.

10. An apparatus configured to communicate with a light detection and ranging (LIDAR) system that is associated with a first object in a traffic environment, the apparatus comprising:
an acquisition and information unit configured to detect a signal pulse emitted by the LIDAR system;
a control device configured to determine if the detected signal pulse satisfies at least one threshold setting; and
a signal generating device configured to, in response to the detected signal pulse satisfying the at least one threshold setting, output an information signal noticeable by human senses.

11. The apparatus of claim 10, wherein the information signal includes at least one of an optical signal, an acoustic signal, and a mechanical vibration.

12. The apparatus of claim 10, wherein the signal pulse comprises at least one of an object type, an object classification, an object velocity, an object trajectory, a position, a distance, an acceleration, and a method of movement of the first object.

13. The apparatus of claim 12, wherein the at least one of an object type, an object classification, an object velocity, an object trajectory, a position, a distance, an acceleration, and a method of movement of the first object is included in the signal pulse by frequency modulation, pulse modulation or a pulse code.

14. The apparatus of claim 10, wherein the information signal includes an optical signal and wherein the signal generating device comprises one or more light sources and one or more optical waveguides, wherein each of the one or more optical waveguides is configured to be coupled to a respective one of the one or more light sources to output the optical signal over a length of the optical waveguide.

15. The apparatus of claim 10, wherein the signal generating device comprises one or more self-luminous fibers each of which is configured to output the information signal passively or actively.

16. The apparatus of claim 10, wherein the acquisition and information unit includes a detector including a plurality of detector elements each of which is positioned in a respective one of a plurality of acceptance angles.

17. The apparatus of claim 16, wherein the plurality of acceptance angles overlap with respect to each other.

18. The apparatus of claim 16, wherein the acquisition and information unit is disposed on a garment.

19. The apparatus of claim 10, wherein the at least one threshold setting is selectable.

20. The apparatus of claim 10, wherein the control device is further configured to adapt the at least one threshold setting based on sensed motion characteristics of the first object.

21. The apparatus of claim 10, wherein the acquisition and information unit includes a plurality of photodiodes arranged horizontally with overlapping acceptance angles or one or more band filters to pass through the signal pulse in a particular wavelength.

22. The apparatus of claim 10, wherein the signal generating device is configured to output the information signal with a quality that is determined in accordance with the detected signal pulse.

23. The apparatus of claim 10, wherein the signal generating device includes a rigid or flexible flat screen display device, a smartphone, a smart watch, or an augmented reality device.

24. An apparatus disposed on an object located in a field of view (FOV) of a LIDAR system, the apparatus comprising:
a receiver configured to receive a plurality of first pulses emitted by the LIDAR system; and
a radiator configured to be excited by the plurality of first pulses and to emit a plurality of second pulses, wherein the plurality of second pulses indicates object information associated with the object.
